(19) United States
(12) Patent Application Publication
(10) Pub. No.: US 2024/0004649 A1
(43) Pub. Date: Jan. 4, 2024

(54) METHOD AND APPARATUS FOR COMPRESSING VECTOR DATA, METHOD AND APPARATUS FOR DECOMPRESSING VECTOR DATA, AND DEVICE

(71) Applicant: Tencent Technology (Shenzhen) Company Limited, Shenzhen (CN)

(72) Inventors: Zimu REN, Shenzhen (CN); Dongsheng Li, Shenzhen (CN)

(73) Assignee: Tencent Technology (Shenzhen) Company Limited, Shenzhen (CN)

(21) Appl. No.: 18/368,419

(22) Filed: Sep. 14, 2023

Related U.S. Application Data
(63) Continuation of application No. PCT/CN2023/076244, filed on Feb. 15, 2023.

(30) Foreign Application Priority Data
Mar. 28, 2022 (CN) 2022103126114

(51) Int. Cl. G06F 9/30

(52) U.S. Cl. CPC G06F 9/30036; G06F 9/30029; G06F 9/30032

(57) ABSTRACT

The present subject matter relates to the field of data processing technologies. Source vector data is stored in a source vector register. The source vector data is divided into n source sub-vectors. The n source sub-vectors are in a one-to-one correspondence with n sets of multiplexers. First valid elements in a source sub-vector are selectively arranged by multiplexers in the n sets of multiplexers in the source vector data to obtain a target sub-vector. A data merging apparatus shifts and merges n target sub-vectors corresponding to the n source sub-vectors to obtain target vector data. A target vector register stores second valid elements in the target vector data. Through the method, the apparatus, and the device, a congestion level of wires can be effectively reduced, thereby significantly reducing an area of a processor.

### RELATED APPLICATION

This application is a continuation of PCT Application PCT/CN2023/076224 filed Feb. 15, 2023, which claims priority to Chinese Patent Application No. 202210312611.4, entitled “METHOD AND APPARATUS FOR COMPRESSING VECTOR DATA, METHOD AND APPARATUS FOR DECOMPRESSING VECTOR DATA, AND DEVICE” filed on Mar. 28, 2022. All are incorporated herein by reference in their entireties.

### FIELD OF THE TECHNOLOGY

The present subject matter relates to the field of data processing technologies, and in particular, to a method and an apparatus for compressing vector data, a method and an apparatus for decompressing vector data, and a device.

### BACKGROUND OF THE DISCLOSURE

Currently, some mainstream artificial intelligence (AI) processors in the industry are designed with a data compression instruction, which may be used for accelerating the inference and training efficiency of the AI processors. An implementation of the data compression instruction has significant impact on the AI processors.

In related art, the data compression instruction is implemented through direct compression of vector data by using a set of multiplexers (MUX). For example, during compression of vector data with 16 elements, 15 MUXes need to be arranged. The 15 MUXes are successively 16-1 MUX, 15-1 MUX, . . . , and 2-1 MUX in ascending order of bits.

### SUMMARY

Examples of the present subject matter provide a method and an apparatus for compressing vector data, a method and an apparatus for decompressing vector data, and a device, which can reduce a congestion level of wire required for implementing a data compression instruction in an AI processor, and reduce an area of the AI processor. The technical solutions may include the following contents.

According to the present subject matter, a method for compressing and decompressing vector data by a processor comprising a source vector register, a target vector register, n sets of multiplexers, a data merging apparatus, and a data splitting apparatus, where n is an integer greater than 1. The method includes:

compressing the vector data, comprising: storing, by the source vector register, source vector data, wherein the source vector data is divided into n source sub-vectors, and the n source sub-vectors are in a one-to-one correspondence with the n sets of multiplexers; selectively arranging, by an i^{th} set of multiplexers in the n sets of multiplexers, first valid elements in an i^{th} source sub-vector in the source vector data to obtain an i^{th} target sub-vector corresponding to the i^{th} source sub-vector, wherein the first valid elements in the i^{th} target sub-vector are located at a header of the i^{th} target sub-vector, and i is a positive integer less than or equal to n; shifting and merging, by the data merging apparatus, n target sub-vectors corresponding to the n source sub-vectors to obtain target vector data, wherein second valid elements in the target vector data are located at a first header of the target vector data; storing, by the target vector register, the second valid elements in the target vector data; and decompressing the vector data, wherein third valid elements in the target vector data are located at a second header of the target vector data; shifting and splitting, by the data splitting apparatus, the target vector data to obtain n target sub-vectors, wherein fourth valid elements in each of the target sub-vectors are located at a header of the target sub-vector; and respectively decompressing, by the n sets of multiplexers, the n target sub-vectors to obtain the n source sub-vectors, wherein the n source sub-vectors are configured to be combined to obtain source vector data.

Counterpart device and non-transitory computer-readable medium of the above method are also contemplated.

According to the present subject matter, a method for compressing vector data is provided, the method is executed by a processor, the processor including a source vector register, n sets of multiplexers, a data merging apparatus, and a target vector register, n is an integer greater than 1.

The method includes:
storing, by the source vector register, source vector data, the source vector data is divided into n source sub-vectors, the n source sub-vectors are in a one-to-one correspondence with the n sets of multiplexers;
selectively arranging, by an i^{th} set of multiplexers in the n sets of multiplexers, valid elements in an i^{th} source sub-vector in the source vector data, to obtain an i^{th} target sub-vector corresponding to the i^{th} source sub-vector, valid elements in the i^{th} target sub-vector is located at a header of the i^{th} target sub-vector, and i is a positive integer less than or equal to n;
shifting and merging, by the data merging apparatus, n target sub-vectors corresponding to the n source sub-vectors, to obtain target vector data, valid elements in the target vector data is located at a header of the target vector data; and
storing, by the target vector register, the valid elements in the target vector data.

According to the present subject matter, a method for decompressing vector data is provided, the method is executed by a processor, the processor including a target vector register, a data splitting apparatus, and n sets of multiplexers, n is an integer greater than 1.

The method includes:
storing, by the target vector register, target vector data, valid elements in the target vector data is located at a header of the target vector data;
shifting and splitting, by the data splitting apparatus, the target vector data, to obtain n target sub-vectors, valid elements in each of the target sub-vectors are located at a header of the target sub-vector; and
respectively decompressing, by the n sets of multiplexers, the n target sub-vectors, to obtain n source sub-vectors, the n source sub-vectors are configured to be combined to obtain source vector data.

According to the present subject matter, a processor is provided, the processor including a source vector register, n sets of multiplexers, a data merging apparatus, and a target vector register, each set of multiplexers including at least two multiplexers, and n is an integer greater than 1;
the source vector register including n sets of output ports, the n sets of output ports are respectively connected to input ports of the n sets of multiplexers;
output ports of the n sets of multiplexers are connected to an input port of the data merging apparatus; and
an input port of the target vector register is connected to an output port of the data merging apparatus.

According to the present subject matter, a processor is provided, the processor including a target vector register, a data splitting apparatus, and n sets of multiplexers, each set of multiplexers including at least two multiplexers, and n is an integer greater than 1;
an output port of the target vector register is connected to an input port of the data splitting apparatus; and
an output port of the data splitting apparatus are connected to input ports of the n sets of multiplexers.

According to the present subject matter, a computer device is provided, the computer device including a processor and a memory, the memory storing at least one instruction, at least one program, a code set, or an instruction set, the at least one instruction, the at least one program, the code set, or the instruction set is loaded and executed by the processor to cause the computer device to implement the foregoing method for compressing vector data, or implement the foregoing method for decompressing vector data.

According to the present subject matter, a non-transitory computer-readable storage medium is provided, the non-transitory computer-readable storage medium storing at least one instruction, at least one program, a code set, or an instruction set, the at least one instruction, the at least one program, the code set, or the instruction set is loaded and executed by a processor to cause a computer to implement the foregoing method for compressing vector data, or implement the foregoing method for decompressing vector data.

According to the present subject matter, a computer program product or a computer program is provided, the computer program product or the computer program including computer instructions, the computer instructions are stored in a non-volatile computer-readable storage medium. A processor of a computer device reads the computer instructions from the non-volatile computer-readable storage medium, and executes the computer instructions to cause the computer device to perform the foregoing method for compressing vector data or implement the foregoing decompressing for method vector data.

The n source sub-vectors divided from the source vector data are compressed respectively by using the n sets of multiplexers, to obtain the n target sub-vectors. Then, the n target sub-vectors are shifted and merged to obtain the target vector data, that is, compressed source vector data. In this way, divide-and-conquer processing of vector data is implemented. Therefore, a plurality of multiplexers with a high parallelism degree are not required, a quantity of access ports of the multiplexers can be reduced, and a quantity of multiplexers to which the output ports of the source vector register need to be connected is reduced, thereby reducing a quantity of wires required for vector data compression in the processor and wire intersections are reduced, significantly reducing a congestion level of the wires required for vector data compression in the processor, and significantly reducing an area of the processor, especially an area of a processor with a high vector processing parallelism degree. The reduction of the area of the processor reduces manufacturing difficulty and manufacturing costs of the processor.

In addition, since the n source sub-vectors are compressed respectively by using the n sets of multiplexers, a compression delay of the vector data is reduced, and compression efficiency of the vector data is improved.

### BRIEF DESCRIPTION OF THE DRAWINGS

FIG. 1 is a schematic diagram of a processor (corresponding to vector data compression) in the related art.

FIG. 2 is a schematic diagram of a processor (corresponding to vector data compression) according to an example of the present subject matter.

FIG. 3 is a schematic diagram of a processor (corresponding to vector data compression) according to another example of the present subject matter.

FIG. 4 is a flowchart of a method for compressing vector data according to an example of the present subject matter.

FIG. 5 is a schematic diagram of source vector data and compressed source vector data according to an example of the present subject matter.

FIG. 6 is a schematic diagram of a source sub-vector and a compressed source sub-vector according to an example of the present subject matter.

FIG. 7 is a schematic diagram of a method for merging a to-be-merged vector according to an example of the present subject matter.

FIG. 8 is a schematic diagram of a method for obtaining a filled to-be-merged vector according to an example of the present subject matter.

FIG. 9 is a schematic diagram of a processor (corresponding to vector data decompression) according to an example of the present subject matter.

FIG. 10 is a schematic diagram of a processor (corresponding to vector data decompression) according to another example of the present subject matter.

FIG. 11 is a flowchart of a method for decompressing vector data according to an example of the present subject matter.

FIG. 12 is a schematic diagram of target vector data and decompressed target vector data according to an example of the present subject matter.

FIG. 13 is a schematic diagram of a target sub-vector and a decompressed target sub-vector according to an example of the present subject matter.

FIG. 14 is a schematic diagram of a method for splitting a to-be-split vector according to an example of the present subject matter.

FIG. 15 is a block diagram of an apparatus for compressing vector data according to an example of the present subject matter.

FIG. 16 is a block diagram of an apparatus for decompressing vector data according to an example of the present subject matter.

FIG. 17 is a block diagram of a computer device according to an example of the present subject matter.

### DETAILED DESCRIPTION

In order to make objectives, technical solutions, and advantages of the present subject matter clearer, implementations of the present subject matter are further described in detail below with reference to the drawings.

In the related art, a plurality of MUXes are usually used to compress entire vector data (or vector data). For example, the MUXes successively select an element from the vector data based on a data compression instruction, so that valid elements in the vector data are concentrated at a header of the vector data, and invalid elements in the vector data are concentrated at a tail of the vector data, thereby obtaining compressed vector data. A valid element may be an element useful for inference and training of a processor (such as an AI processor), and an invalid element may be an element useless for inference and training of a processor (such as an AI processor). In the related art, as a vector processing parallelism degree of the AI processor increases, a quantity of required MUXes increases, and a quantity of MUX ports increases sharply, which results in severe wire congestion and a large area of the AI processor.

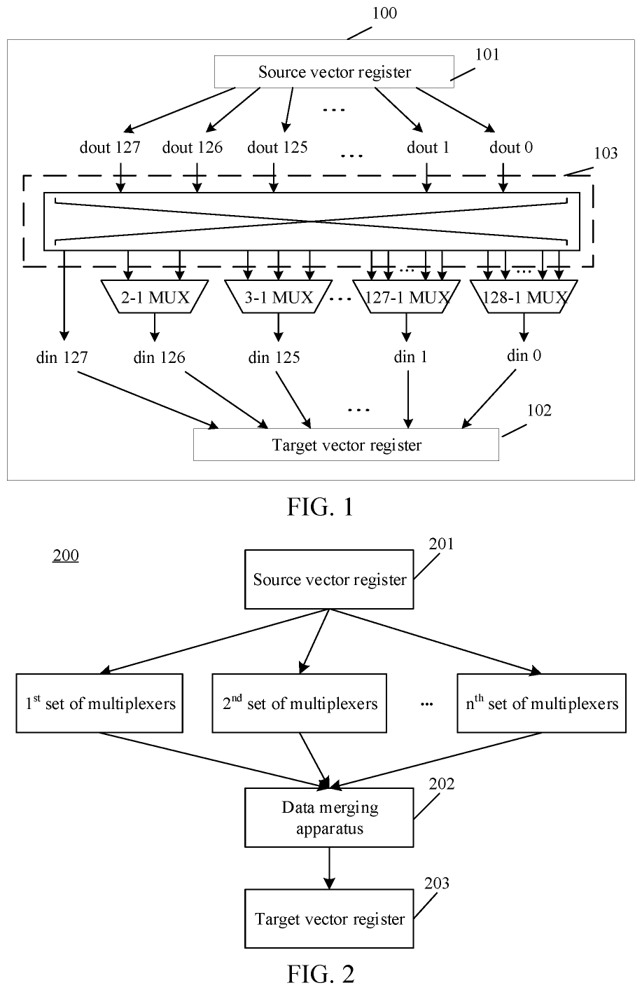

For example, FIG. 1 is a schematic diagram of a processor according to the related art. A vector processing parallelism degree of a processor 100 is 128, that is, 128 elements are simultaneously input into the processor 100. The processor 100 may be an AI processor. The processor 100 may be configured to execute a data compression instruction. The data compression instruction is an instruction to compress valid elements in source vector data to a header and crow invalid elements out. Optionally, the processor 100 may be an AI chip. The processor 100 may also be referred to as a vector compression unit. This is not limited in the examples of the present subject matter.

The processor 100 includes a source vector register 101, a target vector register 102, and 127 multiplexers. The source vector register 101 is configured to store source vector data. The source vector data is to-be-compressed vector data. Optionally, the source vector register 101 has 128 output ports, which are successively dout 0 to dout 127 in ascending order of bis (that is, from right to left).

The 127 multiplexers are successively: 128-1 multiplexer (128-1 MUX), 127-1 multiplexer (127-1 MUX), 2-1 multiplexer (2-1 MUX) in ascending order of bis. An input port of the 128-1 multiplexer is connected to the 128 output ports of the source vector register 101 (optionally, any connection regarding a port herein is an electrical connection), and is configured to select the 1^{st} valid element (in ascending order of bits) from the 128 elements corresponding to the source vector data. An output port of the 128-1 multiplexer is connected to an input port din 0 of the target vector register 102, and is configured to input the 1^{st} valid element into the target vector register 102. The target vector register 102 is configured to store target vector data, that is, compressed source vector data. Optionally, the target vector register 102 may be configured to store valid elements in the target vector data. Optionally, the target vector register 102 has 128 input ports, which are successively din 0 to din 127 in ascending order of bis (that is, from right to left).

An input port of the 127-1 multiplexer is connected to the 127^{th} high-bit output port of the source vector register 101 (that is, the 127^{th} output port starting from the left), and is configured to select the 2^{nd} valid element from the 127 elements corresponding to the source vector data (excluding an element corresponding to dout 0). An output port of the 127-1 multiplexer is connected to the input port din 1 of the target vector register 102, and is configured to output the 2^{nd} valid element into the target vector register 102.

Through the 127 multiplexers, the elements in the source vector data can be selectively arranged, to obtain the compressed source vector data, that is, the target vector data. The output port dout 127 of the source vector register is directly connected to the input port din 127 of the target vector register. In this way, the last element corresponding to the source vector data can be directly input into the target vector register.

It may be learned that, based on the foregoing hardware architecture required for data compression, in a case that the processor has a high vector processing parallelism degree, a large quantity of wires exist in a wire region 103. For example, if the vector processing parallelism degree of the processor is 128, 128+127+126+ . . . +3+2+1=8256 wires exist in the wire region 103. In this case, as the vector processing parallelism degree of the processor increases, the quantity of wires in the wire region 103 increases sharply, which significantly increases a wire congestion level, and even results in a failure in convergence, causing excessively large wire pressure. In addition, an area of the processor 100 is significantly increased, resulting in an increase in manufacturing difficulty and manufacturing costs of the processor. Moreover, in the wire region 103, many wires intersect. For example, the output port dout 127 of the source vector register needs to be connected to each multiplexer, and the output port dout 126 of the source vector register also needs to be connected to each multiplexer, which causes a plurality of wire intersections. As the vector processing parallelism degree of the processor increases, wire intersections increase, which further increases the wire pressure.

The examples of the present subject matter provide a method for compressing vector data, which can realize divide-and-conquer processing of the vector data. Therefore, a plurality of multiplexers with a high parallelism degree are not required, a quantity of access ports of the multiplexers can be reduced, and a quantity of multiplexers to which the output ports of the source vector register need to be connected is reduced, thereby reducing a quantity of wires required for vector data compression in the processor and wire intersections are reduced, significantly reducing a congestion level of the wires required for vector data compression in the processor, and significantly reducing an area of the processor, especially an area of a processor with a high vector processing parallelism degree. The reduction of the area of the processor reduces manufacturing difficulty and manufacturing costs of the processor. The method for compressing vector data provided in the present subject matter is described in detail below.

FIG. 2 is a schematic diagram of a processor according to an example of the present subject matter. A processor 200 includes a source vector register 201, n sets of multiplexers, a data merging apparatus 202, and a target vector register 203. Each set of multiplexers include at least two multiplexers, and n is an integer greater than 1.

The source vector register 201 includes n sets of output ports, the n sets of output ports are respectively connected to input ports of then sets of multiplexers. A p^{th} set of output ports in the n sets of output ports are connected to input ports of a p^{th} set of multiplexers in the n sets of multiplexers, p is a positive integer less than or equal to n.

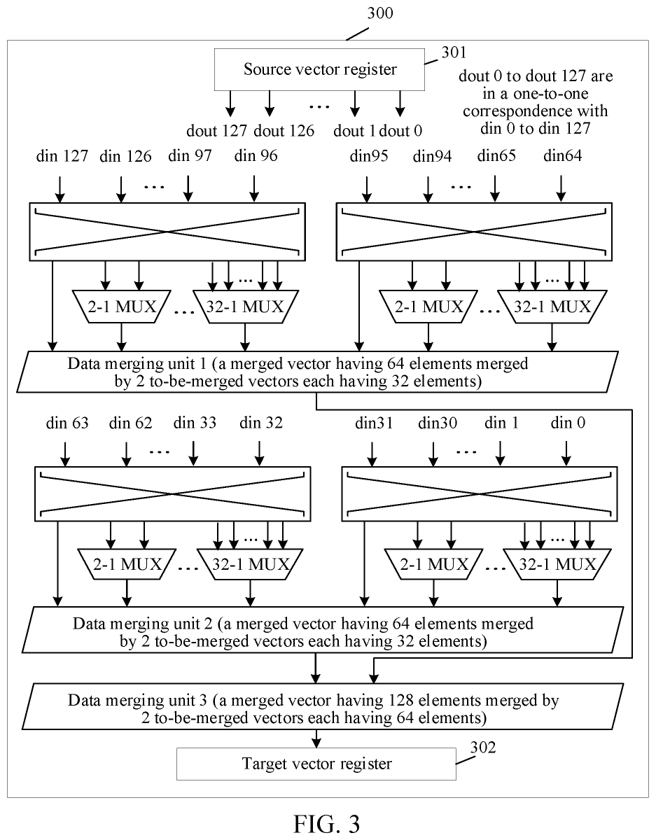

For example, referring to FIG. 3, the vector processing parallelism degree of the processor is 128. 128 output ports (that is, dout 127 to dout 0 in FIG. 3) of a source vector register 301 are divided into 4 sets. The 1^{st} set of output ports (dout 127 to dout 96) are connected to input ports (din 127 to din 96) of the 1^{st} set of multiplexers in a one-to-one correspondence. The 2^{nd} set of output ports (dout 95 to dout 64) are connected to input ports (din 95 to din 64) of the 2^{nd} set of multiplexers in a one-to-one correspondence. The 3^{rd} set of output ports (dout 63 to dout 32) are connected to input ports (din 63 to din 32) of the 3^{rd} set of multiplexers in a one-to-one correspondence. The 4^{th} set of output ports (dout 31 to dout 0) are connected to input ports (din 31 to din 0) of the 4^{th} set of multiplexers in a one-to-one correspondence.

Optionally, n may be set as an integer multiple of 2, such as 2, 4, or 6, to facilitate arrangement of hardware of the processor, such as wires and multiplexers. This is not limited in this example of the present subject matter.

In an example, the p^{th} set of output ports include x output ports, and the p^{th} set of multiplexers include x−1 multiplexers, x is a positive integer. The p^{th} set of output ports may be any set of output ports in the n sets of output ports. Optionally, the n sets of output ports may be uniformly divided, or each set of output ports may be configured with different output port quantities. This is not limited in this example of the present subject matter. For example, referring to FIG. 3, each set of output ports include 32 output ports, and therefore each set of multiplexers include 31 multiplexers.

Optionally, an a^{th} multiplexer in the x−1 multiplexers includes x−a+1 input ports in ascending order of bits, the x−a+1 input ports corresponding to the a^{th} multiplexer is connected to x−a+1 output ports of the p^{th} set of output ports in a one-to-one correspondence in descending order of bits, a is a positive integer less than x.

For example, referring to FIG. 3, the 1^{st} multiplexer (that is, a 32-1 multiplexer) in the 1^{st} set of multiplexers (din 127 to din 96) includes 32−1+1=32 input ports in ascending order of bits. The 32 input ports of the 1^{st} multiplexer are in connected to 32 output ports of the 1^{st} set of output ports (dout 127 to dout 96) in a one-to-one correspondence in descending order of bits. For another example, in ascending order of bits, the 2^{nd} multiplexer (that is, a 31-1 multiplexer, which is not shown in FIG. 3) in the 1^{st} set of multiplexers (din 127 to din 96) includes 32−2+1=31 input ports. The 31 input ports of the 2^{nd} multiplexer are connected in a one-to-one correspondence to 31 output ports (that is, dout 127 to dout 97) of the 1^{st} set of output ports (dout 127 to dout 96) starting from left in descending order of bits.

Optionally, a first output port of the p^{th} set of output ports is connected to an input port of the data merging apparatus 202. The first output port is the first one of the output ports corresponding to the p^{th} set of output ports in descending order of bits. For example, referring to FIG. 3, the 1^{st} output port (that is, dout 127) of the 1^{st} set of output ports is directly connected to an input port of a data merging unit 1 in the data merging apparatus.

In an example, output ports of the n sets of multiplexers are connected to the input port of the data merging apparatus 202. For example, the data merging apparatus 202 includes m sets of data merging units, m is a positive integer.

Input ports of data merging units in the first set of data merging units are respectively connected to output ports of two adjacent sets of multiplexers. For example, referring to FIG. 3, the data merging apparatus includes 2 sets of data merging units. The 1^{st} set of data merging units include the data merging unit 1 and a data merging unit 2. The 2^{nd} set of data merging units include a data merging unit 3. The input port of the data merging unit 1 is connected to the output ports (din 127 to din 96) of the 1^{st} set of multiplexers and output ports (din 95 to din 64) of the 2^{nd} set of multiplexers. An input port of the data merging unit 2 is connected to output ports (din 63 to din 32) of the 3^{rd} set of multiplexers and output ports (din 31 to din 0) of the 4^{th} set of multiplexers.

Optionally, input ports of the data merging units in a z^{th} set of data merging units are respectively connected to output ports of adjacent data merging units in a (z−1)^{th} set of data merging units, z is an integer greater than 1. For example, referring to FIG. 3, an input port of the data merging unit 3 in the 2^{nd} set of data merging units is connected to an output port of the data merging unit 1 and an output port of the data merging unit 2 in the 1^{st} set of data merging units.

Optionally, in a case that a quantity of the data merging units in the z^{th} set of data merging units is an odd number, an output port of a target data merging unit in the z^{th} set of data merging units is connected to an input port of a target data merging unit in a (z+1)^{th} set of data merging units, the target data merging unit is the last data merging unit or the first data merging unit in each set of data merging units in descending order of bits. For example, in a case that the quantity of the data merging units in the 1^{st} set of data merging units is 3, an output port of the last data merging unit in the 1^{st} set of data merging units is connected to an input port of the last data merging unit in the 2^{nd} set of data merging units; or an output port of the first data merging unit in the 1^{st} set of data merging units is connected to an input port of the first data merging unit in the 2^{nd} set of data merging units.

An input port of the target vector register 203 is connected to an output port of the data merging apparatus 202. Exemplarily, output ports of the last set of data merging units in the m sets of data merging units are connected to the input port of the target vector register 203. For example, referring to FIG. 3, an output port of the data merging unit 3 is connected to the input port of the target vector register 302.

Optionally, the data merging unit may be formed by a combination of a shifter and a multiplexer. Exemplarily, the data merging unit may be formed by a combination of a barrel shifter and a 2-1 multiplexer. A method for merging vector data through the barrel shifter and the 2-1 multiplexer will be described below, and therefore is not described herein.

In an example, referring to FIG. 3, 32+31+ . . . +3+2+1=528 wires exist in a wire region corresponding to each set of multiplexers. In this case, a total of 528*4=2112 wires exist, which is much less than 8256 wires in the related art. In this way, wire pressure and a required wire area are reduced. In addition, since the quantity of wires is significantly reduced, wire intersections is significantly reduced.

A design compiler (a tool configured for circuit synthesis) is used to synthesize data compression hardware in the related art and data compression hardware (such as the processor 100 and the processor 300) in the present subject matter. An area of the processor corresponding to the related art is 1031 μm\hat{ }2, while the area of the processor corresponding to the present subject matter is 711 μm\hat{ }2. Therefore, it may be learned that the area of the processor required for implementing the data compression instruction in the present subject matter is significantly less than the area of the processor corresponding to the related art, which is merely 69% of the area of the processor corresponding to the related art. In addition, as the vector processing parallelism degree of the processor increases, the area of the processor is reduced to a larger extent.

In summary, in the technical resolutions provided in the examples of the present subject matter, n source sub-vectors divided from the source vector data are compressed respectively by using the n sets of multiplexers, to obtain n target sub-vectors. Then, the n target sub-vectors are shifted and merged to obtain target vector data, that is, compressed source vector data. In this way, divide-and-conquer processing of vector data is implemented. Therefore, a plurality of multiplexers with a high parallelism degree are not required, a quantity of access ports of the multiplexers can be reduced, and a quantity of multiplexers to which the output ports of the source vector register need to be connected is reduced, thereby reducing a quantity of wires required for vector data compression in the processor and wire intersections are reduced, significantly reducing a congestion level of the wires required for vector data compression in the processor, and significantly reducing an area of the processor, especially an area of a processor with a high vector processing parallelism degree. The reduction of the area of the processor reduces manufacturing difficulty and manufacturing costs of the processor.

In addition, since the n source sub-vectors are compressed respectively by using the n sets of multiplexers, a compression delay of the vector data is reduced, and compression efficiency of the vector data is improved.

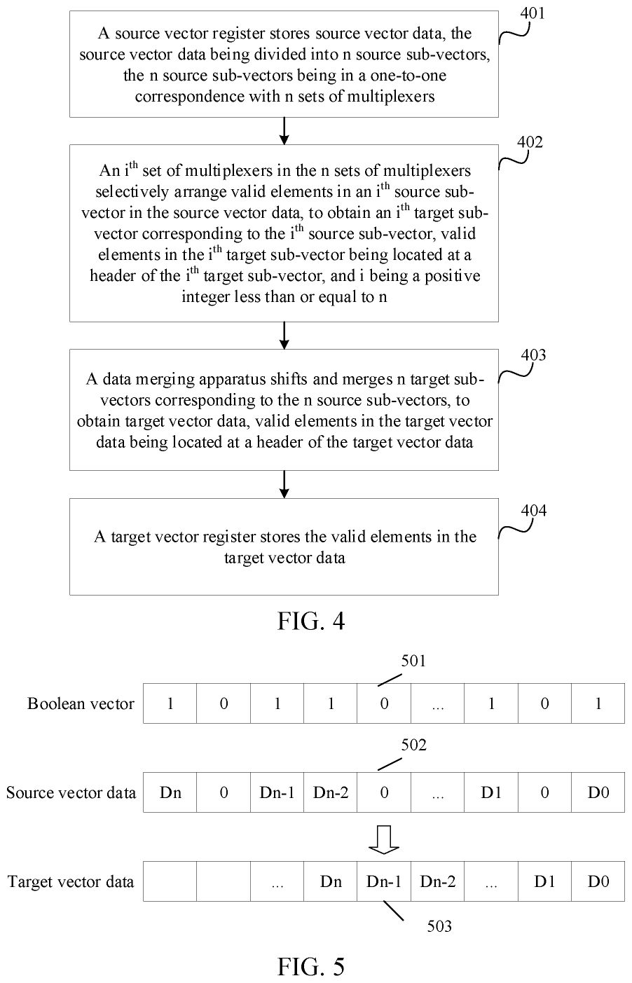

FIG. 4 is a flowchart of a method for compressing vector data according to an example of the present subject matter. The method is performed by a processor, such as the processor shown in FIG. 2. The method may include the following steps (401-404).

Step 401: A source vector register stores source vector data, the source vector data is divided into n source sub-vectors, the n source sub-vectors are in a one-to-one correspondence with n sets of multiplexers.

The source vector register is a register configured to store source vector data. The processor may invoke the source vector data from the source vector register based on a data compression instruction. The source vector data is to-be-compressed vector data. In this example of the present subject matter, a quantity of elements in the source vector data may be determined based on a vector processing parallelism degree of the processor. For example, the quantity of elements in the source vector data may be the same as the vector processing parallelism degree of the processor.

Optionally, the source vector data may include both valid and invalid elements. A valid element may be an element useful for inference and training of a processor (such as an AI processor), and an invalid element may be an element useless for inference and training of a processor (such as an AI processor). In some examples, the processor not only invokes the source vector data, but also invokes a boolean vector associated with the source vector data. Elements in the boolean vector are configured to indicate a distribution of the valid elements in the source vector data. The boolean vector may be stored in the source vector register or in another register. This is not limited in this example of the present subject matter. For example, referring to FIG. 5, each element in a boolean vector 501 is a boolean value. 1 indicates that an element at a corresponding position in source vector data 502 is a valid element. 0 indicates that an element at the corresponding position in the source vector data 502 is an invalid element. In a subsequent vector data compression process, the invalid elements need to be crowded out.

This example of the present subject matter introduces a divide-and-conquer strategy, in which the elements of the source vector data are divided into groups for compression (for example, divided into groups for parallel compression) during compression of the source vector data. Exemplarily, referring to FIG. 3, the source vector data is divided into 4 source sub-vectors. Each of the source sub-vectors corresponds to one set of elements in the source vector data. Quantities of elements in the source vector data included in different source sub-vectors may be the same or different. For example, source vector data with 128 elements is uniformly divided into 4 source sub-vectors with 32 elements in descending order of bits. Each 4 source sub-vectors correspond to one set of multiplexers. Each set of multiplexers are configured to compress corresponding source sub-vectors.

Step 402: An i^{th} set of multiplexers in the n sets of multiplexers selectively arrange valid elements in an i^{th} source sub-vector in the source vector data, to obtain an i^{th} target sub-vector corresponding to the i^{th} source sub-vector, valid elements in the i^{th} target sub-vector is located at a header of the i^{th} target sub-vector, and i is a positive integer less than or equal to n.

The i^{th} set of multiplexers may be any set of multiplexers in the n sets of multiplexers. The i^{th} source sub-vector is a source sub-vector corresponding to the i^{th} set of multiplexers. For example, referring to FIG. 3, in descending order of bits, the 1^{st} source sub-vector (composed of elements corresponding to dout 127 to dout 96) corresponds to the 1^{st} set of multiplexers (din 127 to din 96). The 2nd source sub-vector (composed of elements corresponding to dout 95 to dout 64) corresponds to the 2^{nd} set of multiplexers (din 95 to din 64). The 3^{rd} source sub-vector (composed of elements corresponding to dout 63 to dout 32) corresponds to the 3^{rd} set of multiplexers (din 63 to din 32). The 4^{th} source sub-vector (composed of elements corresponding to dout 31 to dout 0) corresponds to the 4^{th} set of multiplexers (din 31 to din 0).

In an example, a quantity of multiplexers in each set of multiplexers may be determined based on a quantity of elements in the source sub-vector. Exemplarily, the i^{th} source sub-vector includes x elements, the x elements including y valid elements, and the i^{th} set of multiplexers include x−1 multiplexers of different types, x is a positive integer, and y is a positive integer less than or equal to x. For example, referring to FIG. 3, in a case that the 1^{st} source sub-vector (composed of the elements corresponding to dout 127 to dout 96) includes 32 elements, the 1^{st} set of multiplexers corresponding to the 1^{st} source sub-vector include 31 multiplexers of different types. In an example, y is a positive integer less than or equal to x−1.

For example, in a compression process of the i^{th} source sub-vector, an obtaining process of the i^{th} target sub-vector corresponding to the i^{th} source sub-vector may include: selecting, by y multiplexers in the x−1 multiplexers, the y valid elements from the x elements in ascending order of bits based on a boolean vector corresponding to the source vector data, and arranging the y valid elements in ascending order of bits, to obtain the i^{th} target sub-vector.

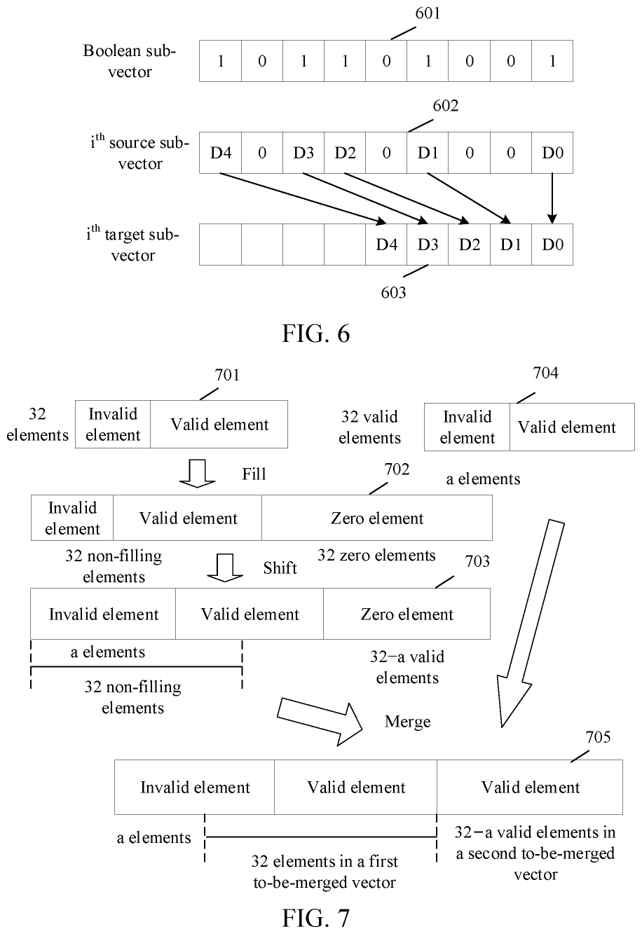

For example, referring to FIG. 6, an i^{th} source sub-vector 602 includes 9 elements. The 9 elements include 5 valid elements, which are successively D0, D1, D2, D3, and D4 in ascending order of bits. The i^{th} source sub-vector 602 corresponds to 5 multiplexers of a set of multiplexers starting from right. Based on a boolean sub-vector 601 (that is, composed of elements in the boolean vector corresponding to the i^{th} source sub-vector), the 5 valid elements are selected from the 9 elements in ascending order of bits, and the 5 valid elements are arranged in ascending order of bits to obtain an i^{th} target sub-vector 603. The 5 valid elements in the i^{th} target sub-vector are arranged in sequence at a header of the i^{th} target sub-vector 603. Optionally, remaining invalid elements may be arranged in sequence at remaining positions in the i^{th} target sub-vector 603 in ascending order of bits.

In an example, a specific determination process of an element at each position in the i^{th} target sub-vector may include: selecting, by a z^{th} multiplexer in the y multiplexers, a z^{th} valid element from a z^{th} element to an x^{th} element in the i^{th} source sub-vector in ascending order of bits based on the boolean vector, z is a positive integer less than or equal to y; and adding, by the z^{th} multiplexer, the z^{th} valid element to a z^{th} position of the i^{th} target sub-vector. The z^{th} multiplexer may be any one of the y multiplexers.

For example, referring to FIG. 6, in ascending order of bits, the 1^{st} multiplexer selects the 1^{st} valid element D0 from the 1^{st} to 9^{th} elements in the i^{th} source sub-vector 602 based on the boolean sub-vector 601, and adds the 1^{st} valid element to the 1^{st} position in the i^{th} target sub-vector 603; the 2^{nd} multiplexer selects the 2^{nd} valid element D1 from the 2nd to 9^{th} elements in the i^{th} source sub-vector 602 based on the boolean sub-vector 601, and adds the 2^{nd} valid element to the 2^{nd} position in the i^{th} target sub-vector 603, and so on. In this way, the 5 valid elements corresponding to the i^{th} source sub-vector 602 may be arranged at the header of the i^{th} target sub-vector 603.

Step 403: A data merging apparatus shifts and merges n target sub-vectors corresponding to the n source sub-vectors to obtain target vector data, valid elements in the target vector data are located at a header of the target vector data.

Exemplarily, the n target sub-vectors may be obtained through selective arrangement of valid elements of the n source sub-vectors performed by the n sets of multiplexers in sequence.

Exemplarily, the n target sub-vectors may alternatively be obtained through selective arrangement of valid elements of the n source sub-vectors performed by the n sets of multiplexers in parallel. In this way, parallel compression of the n source sub-vectors can be realized, thereby further reducing a compression delay of the vector data and improving compression efficiency of the vector data.

Optionally, the data merging apparatus includes m sets of data merging units, the m sets of data merging units are configured to perform p rounds of shifting and merging on the n target sub-vectors to obtain the target vector data, m is an integer greater than 1, and p is a positive integer. For example, referring to FIG. 3, the data merging apparatus includes 2 sets of data merging units. The 1^{st} set of data merging units include the data merging unit 1 and a data merging unit 2. The 2nd set of data merging units include a data merging unit 3. The 2 sets of data merging units are configured to perform 2 rounds of shifting and merging on 4 target sub-vectors (composed of output ports of 4 sets of multiplexers respectively).

Optionally, p may be set to be equal to m. In other words, m sets of data merging units may perform m rounds of shifting and merging on the n target sub-vectors to obtain the target vector data. In some examples, p may alternatively be set to be unequal to m. For example, p may be set to be less than m or greater than m.

The target vector data is vector data obtained after the source vector data is compressed. Optionally, only the valid elements in the source vector data may be retained in the target vector data, or both the valid and invalid elements in the source vector data may be retained. This is not limited in this example of the present subject matter. For example, referring to FIG. 5, through compression of the source vector data 502, target vector data 503 can be obtained. Valid elements (D0 to Dn) in the target vector data 503 are located at a header of the target vector data 503.

In an example, a specific process of the foregoing p rounds of shifting and merging may include: shifting and merging, by a q^{th} set of data merging units in the m sets of data merging units for a q^{th} round of shifting and merging, a q^{th} set of to-be-merged vectors, to obtain a q^{th} set of merged vectors, q is a positive integer less than or equal to p. In a case that q is equal to 1, the q^{th} set of to-be-merged vectors are the n target sub-vectors, and in a case that q is greater than 1, the q^{th} set of to-be-merged vectors are a (q−1)^{th} set of merged vectors, and a p^{th} set of merged vectors are the target vector data.

For example, referring to FIG. 3, the 1^{st} set of data merging units (the data merging unit 1 and the data merging unit 2) are configured to perform the first round of shifting and merging on the 4 target sub-vectors (that is, 4 to-be-merged vectors each having 32 elements) to obtain the 1^{st} set of merged vectors (that is, 2 merged vectors each having 64 elements). The 2nd set of data merging units (the data merging unit 3) are configured to perform the second round of shifting and merging on the 1^{st} set of merged vectors, to obtain the target vector data (that is, 1 merged vector having 128 elements).

In an example, the data merging units in the q^{th} sets of data merging units shift and merge each two adjacent to-be-merged vectors in the q^{th} set of to-be-merged vectors, to obtain the q^{th} set of merged vectors. For example, referring to FIG. 3, the data merging unit 1 in the 1^{st} set of data merging units shifts and merges the 1^{st} target sub-vector (composed of output ports of the 1^{st} set of multiplexers) and the 2^{nd} target sub-vector (composed of output ports of the 2^{nd} set of multiplexers) that are adjacent to each other. The data merging unit 2 in the 1^{st} set of data merging units shifts and merges the 3^{rd} target sub-vector (composed of output ports of the 3^{rd} set of multiplexers) and the 4^{th} target sub-vector (composed of output ports of the 4^{th} set of multiplexers) that are adjacent to each other, to obtain the 1^{st} set of merged vectors.

Exemplarily, the implementation in which the data merging units in the q^{th} sets of data merging units shift and merge each two adjacent to-be-merged vectors in the q^{th} set of to-be-merged vectors, to obtain the q^{th} set of merged vectors is implemented in a case that a quantity of the to-be-merged vectors in the q^{th} set of to-be-merged vectors is an even number. The quantity of the to-be-merged vectors in the q^{th} set of to-be-merged vectors may alternatively be an odd number. Optionally, in a case that a quantity of to-be-merged vectors in the q^{th} set of to-be-merged vectors is an odd number, the data merging apparatus adds a target to-be-merged vector in the q^{th} set of to-be-merged vectors to the q^{th} set of merged vectors. The target to-be-merged vector in the q^{th} set of to-be-merged vectors is the first to-be-merged vector or the last to-be-merged vector in the q^{th} set of to-be-merged vectors in ascending order of bits. For example, in a case that the quantity of the to-be-merged vectors in the q^{th} set of to-be-merged vectors is 3, the 1^{st} to-be-merged vector in the q^{th} set of to-be-merged vectors starting from right may be directly added to the q^{th} set of merged vectors, and the 2^{nd} to-be-merged vector and 3^{rd} to-be-merged vector in the q^{th} set of to-be-merged vectors starting from right may be shifted and merged. Alternatively, the 1^{st} to-be-merged vector in the CO set of to-be-merged vectors starting from left may be directly added to the q^{th} set of merged vectors, and the 2^{nd} to-be-merged vector and 3^{rd} to-be-merged vector in the q^{th} set of to-be-merged vectors starting from left may be shifted and merged.

In an example, in a case that the first data merging unit in the q^{th} set of data merging units shifts and merges the first to-be-merged vector and the second to-be-merged vector in the q^{th} set of to-be-merged vectors, the shifting and merging process may be as follows:

The first data merging unit shifts the first to-be-merged vector based on the second to-be-merged vector, to obtain an adjusted first to-be-merged vector.

An element corresponding to the second to-be-merged vector in the source vector data is at a lower bit than an element corresponding to the first to-be-merged vector in the source vector data. Optionally, the first to-be-merged vector may be referred to as a high-bit to-be-merged vector, and the second to-be-merged vector may be referred to as a low-bit to-be-merged vector. The first data merging unit may be any one data merging unit in the q^{th} set of data merging units. The first to-be-merged vector and the second to-be-merged vector are two to-be-merged vectors corresponding to the first data merging unit adjacent to each other.

Optionally, a specific process of obtaining the adjusted first to-be-merged vector may include: filling, by the first data merging unit, the first to-be-merged vector with elements based on a quantity of elements in the second to-be-merged vector, to obtain a filled first to-be-merged vector, a quantity of elements in the filled first to-be-merged vector is a sum of the quantity of the elements in the second to-be-merged vector and a quantity of elements in the first to-be-merged vector; and shifting, by the first data merging unit, non-filling elements in the filled first to-be-merged vector as a whole based on a quantity of invalid elements in the second to-be-merged vector, to obtain the adjusted first to-be-merged vector, a quantity of non-filling elements corresponding to a header of the adjusted first to-be-merged vector is the same as the quantity of the valid elements in the second to-be-merged vector.

For example, referring to FIG. 7, a first to-be-merged vector 701 has 32 elements, and a second to-be-merged vector 704 has 32 elements. In this case, it may be determined that a filled first to-be-merged vector 702 has 64 elements. Optionally, 32 zero elements are added to a high bit of the first to-be-merged vector 701, then 32 non-filling elements are shifted by 31 bits to the high bit as a whole to obtain the filled first to-be-merged vector 702. Optionally, the 32 non-filling elements may be shifted as a whole by using a shifter. For example, the 32 non-filling elements may be shifted as a whole by using a barrel shifter.

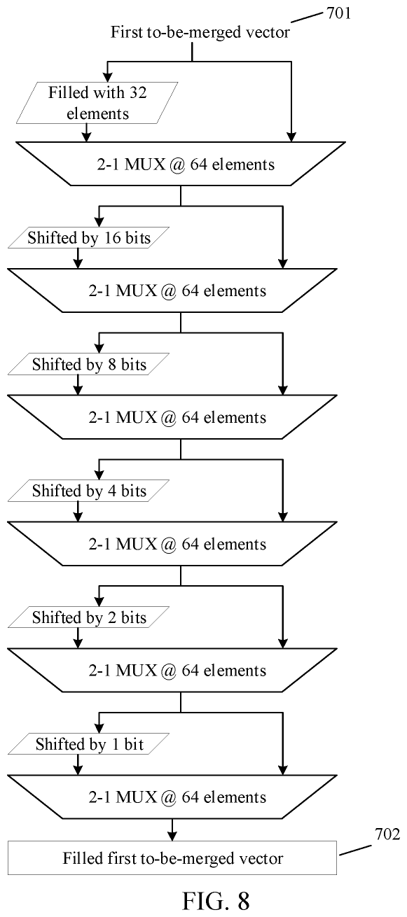

The barrel shifter may be configured to cyclically shift the elements in the vector data leftward. Therefore, a control input merely needs to specify a quantity of to-be-shifted bits. The quantity of to-be-shifted bits is represented a binary numerical string (referred to as S in short below). For example, it is assumed that the barrel shifter corresponds to 64 input ports and 64 output ports. When S=00000, which indicates that the elements need to be cyclically shifted leftward by 0 bits, dout 63=din 63. When S=11111, which indicates that the elements need to be cyclically shifted leftward by 31 bits, and dout 63=din 31. Optionally, shifting may be performed a plurality of times step by step. For example, when S=11111, the elements may be shifted by 16 bits, 8 bits, 4 bits, 2 bits, and 1 bit successively. Exemplarily, referring to FIG. 8, when S=11111, the process may specifically be as follows:

After the first to-be-merged vector 701 is filled with the elements, the first to-be-merged vector 701 filled with the elements and the first to-be-merged vector 701 may be merged by using the 2-1 multiplexer, to obtain a transitional to-be-merged vector with 64 elements. Then S=10000 is set, so that the barrel shifter circularly shifts the non-filling elements leftward by 16 bits. The transitional to-be-merged vector after the first shifting is merged with the transitional to-be-merged vector by using the 2-1 multiplexer, to obtain a first intermediate vector. Then S=01000 is set, so that the barrel shifter circularly shifts the non-filling elements leftward by 8 bits; then S=00100 is set, so that the barrel shifter circularly shifts the non-filling elements leftward by 4 bits; then S=00010 is set, so that the barrel shifter circularly shifts the non-filling elements leftward by 2 bits; and finally S=00001 is set, so that the barrel shifter circularly shifts the non-filling elements leftward by 1 bit, thereby obtaining an adjusted first to-be-merged vector 702.

It is assumed that the second to-be-merged vector 704 includes an invalid elements and 32−a valid elements. In this case, 32 non-filling elements in the filled first to-be-merged vector 702 may be shifted toward a low bit by 32−a−1 bits (that is, S=32−a−1) as a whole through the barrel shifter, to obtain an adjusted first to-be-merged vector 703. A lower bit of the adjusted first to-be-merged vector 703 includes 32−a positions, to place the 32−a valid elements in the second to-be-merged vector 704.

In some examples, the non-filling elements in the first to-be-merged vector filled with the elements may be directly shifted toward the high bit as a whole based on the quantity of valid elements in the second to-be-merged vector, and the quantity of valid elements in the second to-be-merged vector is reduced by 1 bit.

2. The first data merging unit merges the adjusted first to-be-merged vector and the second to-be-merged vector, to obtain a first merged vector corresponding to the q^{th} set of merged vectors.

Optionally, the first data merging unit selects elements corresponding to the first merged vector from the adjusted first to-be-merged vector and the second to-be-merged vector in ascending order of bits. The first data merging unit selects, for a k^{th} element corresponding to the first merged vector, one of a k^{th} element in the adjusted first to-be-merged vector and a k^{th} element in the second to-be-merged vector as the k^{th} element corresponding to the first merged vector, k is a positive integer. The k^{th} element may be any element in the first merged vector.

Exemplarily, in a case that the k^{th} element in the adjusted first to-be-merged vector is a valid element, the first data merging unit determines the k^{th} element in the adjusted first to-be-merged vector as the k^{th} element corresponding to the first merged vector. Alternatively, in a case that the k^{th} element in the second to-be-merged vector is a valid element, the first data merging unit determines the k^{th} element in the second to-be-merged vector as the k^{th} element corresponding to the first merged vector. Exemplarily, the k^{th} element in the adjusted first to-be-merged vector is a valid element means that the k^{th} element in the adjusted first to-be-merged vector is a valid element and the k^{th} element in the second to-be-merged vector is an invalid element. The k^{th} element in the second to-be-merged vector is a valid element means that the k^{th} element in the second to-be-merged vector is a valid element and the k^{th} element in the adjusted first to-be-merged vector is an invalid element.

Exemplarily, in a case that the k^{th} element in the adjusted first to-be-merged vector and the k^{th} element in the second to-be-merged vector are both invalid elements, the first data merging unit may select either of the k^{th} element in the adjusted first to-be-merged vector and the k^{th} element in the second to-be-merged vector as the k^{th} element corresponding to the first merged vector. Exemplarily, in a case that the k^{th} element in the adjusted first to-be-merged vector and the k^{th} element in the second to-be-merged vector are both valid elements, the first data merging unit may select either of the k^{th} element in the adjusted first to-be-merged vector and the k^{th} element in the second to-be-merged vector as the k^{th} element corresponding to the first merged vector.

For example, referring to FIG. 7, a low bit of the adjusted first to-be-merged vector 703 has 32−a positions. Elements corresponding to the 32−a positions are all zero elements, which are equivalent to invalid elements. The 2-1 multiplexer in the first data merging unit has two input ports. One of the input ports is configured to obtain elements corresponding to the adjusted first to-be-merged vector 703. The other input port is configured to obtain the elements corresponding to the second to-be-merged vector 704. For example, in ascending order of bits, the 1^{st} element corresponding to the adjusted first to-be-merged vector 703 is a zero element, and the 1^{st} element corresponding to the second to-be-merged vector 704 is a valid element. Therefore, the 1^{st} element corresponding to the second to-be-merged vector 704 is determined as the 1^{st} element of a first merged vector 705. In this way, the valid elements in the first to-be-merged vector 701 and the second to-be-merged vector 704 may be successively compressed to a header of the first merged vector 705, and an arrangement sequence of the valid elements conforms with the boolean vector. Optionally, when two inputs of the 2-1 multiplexer are both invalid elements, one of the inputs is selected.

After p rounds of shifting and merging, the target vector data may be obtained. During each round of shifting and merging, the elements are shifted by a fixed quantity of bits or not shifted, and an input of each data merging unit has only two vectors, and has no wire intersection, which reduces the wire pressure and the area of the processor.

Step 404: A target vector register stores valid elements in the target vector data.

The target vector register may be configured to store all elements in the target vector data, or store only the valid elements in the target vector data. This is not limited in this example of the present subject matter. Optionally, in a case that the target vector data is required, only the valid elements in the target vector data may be directly invoked. The source vector data may be obtained through decompression based on the valid elements in the target vector data and the boolean vector.

In summary, in the technical resolutions provided in the examples of the present subject matter, the n source sub-vectors divided from the source vector data are compressed respectively by using the n sets of multiplexers, to obtain n target sub-vectors. Then, the n target sub-vectors are shifted and merged to obtain target vector data, that is, compressed source vector data. In this way, divide-and-conquer processing of vector data is implemented. Therefore, a plurality of multiplexers with a high parallelism degree are not required, a quantity of access ports of the multiplexers can be reduced, and a quantity of multiplexers to which the output ports of the source vector register need to be connected is reduced, thereby reducing a quantity of wires required for vector data compression in the processor and wire intersections are reduced, significantly reducing a congestion level of the wires required for vector data compression in the processor, and significantly reducing an area of the processor, especially an area of a processor with a high vector processing parallelism degree. The reduction of the area of the processor reduces manufacturing difficulty and manufacturing costs of the processor.

In addition, since the n source sub-vectors are compressed respectively by using the n sets of multiplexers, a compression delay of the vector data is reduced, and compression efficiency of the vector data is improved. During compression of the n source sub-vectors by using the n sets of multiplexers, the n sets of multiplexers may perform parallel compression on the n source sub-vectors, thereby further reducing the compression delay of the vector data and improving the compression efficiency of the vector data.

In addition, during merging of two adjacent to-be-merged vectors, high-bit to-be-merged vectors are shifted by using a logarithmic shifter, which further reduces the area of the processor.

In addition, hierarchical merging of the to-be-merged vectors facilitates division and realization of a pipeline, which can further improve the compression efficiency of the vector data, thereby improving performance of the data compression instruction.

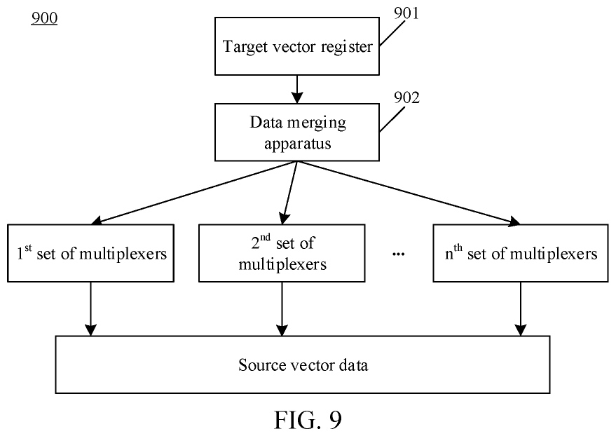

FIG. 9 is a schematic diagram of a processor according to another example of the present subject matter. A processor 900 includes a target vector register 901, a data splitting apparatus 902, and n sets of multiplexers. Each set of multiplexers include at least two multiplexers, and n is an integer greater than 1.

In this example of the present subject matter, the processor 900 is configured to decompress compressed vector data. For example, the processor 900 decompresses target vector data into source vector data based on a boolean vector based on a data decompression instruction. The data decompression instruction is used for indicating that valid elements in the target vector data need to be decompressed to a position specified in the boolean vector and remaining positions need to be filled with invalid data. Optionally, the processor 900 may be an AI processor or an AI chip. The processor 900 may alternatively be referred to a vector decompression unit.

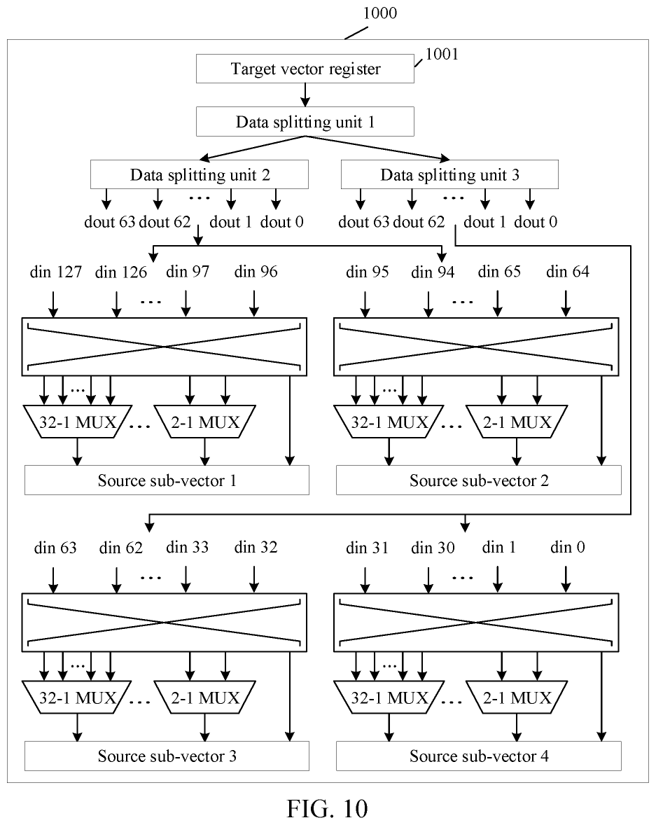

An output port of the target vector register 901 is connected to an input port of the data splitting apparatus 902. Optionally, the data splitting apparatus 902 includes m sets of data splitting units, m is a positive integer. A quantity of data splitting units in each set of data splitting units is not limited in this example of the present subject matter. Exemplarily, referring to FIG. 10, a vector processing parallelism degree of a processor 1000 is 128. In the processor 1000, a data splitting apparatus includes 2 sets of data splitting units. The first set of data splitting units include a data splitting unit 1. The second set of data splitting units include a data splitting unit 2 and a data splitting unit 3.

Optionally, an input port of the data splitting unit in the first set of data splitting units in the m sets of data splitting units is connected to an output port of a target vector register. For any set of data splitting units in the remaining m−1 sets of data splitting units, for example, a z^{th} set of data splitting units, input ports of the data splitting units in the z^{th} set of data splitting units are connected to output ports of data splitting units in a (z−1)^{th} set of data splitting units. z is an integer greater than 1 and not greater than m.

For example, referring to FIG. 10, the input port of the data splitting unit 1 in the first set of data splitting units is connected to an output port of a target vector register 1001. An input port of the data splitting unit 2 in the second set of data splitting units is connected to an output port of the data splitting unit 1. In addition, an input port of the data splitting unit 3 in the second set of data splitting units is connected to the output port of the data splitting unit 1. Optionally, a quantity of connection ports between the data splitting unit 2 and the data splitting unit 1 may be the same as a quantity of connection ports between the data splitting unit 3 and the data splitting unit 1.

An output port of the data splitting apparatus 902 is connected to the input ports of the n sets of multiplexers. Exemplarily, output ports of data splitting units in an m^{th} set of data splitting units are connected to the input ports of the n sets of multiplexers. For example, referring to FIG. 10, the output port of the data splitting unit 2 in the second set of data splitting units is connected to the input ports (din 127 to din 96) of the 1^{st} set of multiplexers and the input ports (din 95 to din 64) of the 2^{nd} set of multiplexers. An output port of the data splitting unit 3 in the second set of data splitting units is connected to the input ports (din 63 to din 32) of the 3^{rd} set of multiplexers and the input ports (din 31 to din 0) of the 4^{th} set of multiplexers.

In an example, for the m^{th} set of data splitting units (that is, the last set of data splitting units), a target data splitting unit in the m^{th} set of data splitting units includes x output ports. The target data splitting unit corresponds to at least two sets of multiplexers. x is a positive integer. For example, referring to FIG. 10, the data splitting unit 2 corresponds to 64 output ports. 32 output ports starting from left are connected in a one-to-one correspondence to the input ports (din 127 to din 96) corresponding to the 1^{st} set of multiplexers. 32 output ports on the right therein are connected in a one-to-one correspondence to input ports (din 95 to din 64) corresponding to the 2^{nd} set of multiplexers. The target data splitting unit is any data splitting unit in the m^{th} set of data splitting units.

Optionally, for a target set of multiplexers corresponding to the target data splitting unit, a quantity of the multiplexers in the target set of multiplexers is equal to a quantity of connection ports between the target data splitting unit and the target set of multiplexers minus 1 (denoted as u−1). The target set of multiplexers are any set of multiplexers of at least two sets of multiplexers corresponding to the target data splitting unit.

Exemplarily, in descending order of bits, a p^{th} multiplexer in the target set of multiplexers includes u−p+1 input ports. The u−p+1 input ports corresponding to the p^{th} multiplexer are connected in a one-to-one correspondence to u output ports corresponding to the target data splitting unit in ascending order of bits. p is a positive integer less than u. A first output port of the target data splitting unit is not connected to the multiplexer. The first output port is the first one of the output ports corresponding to the target data splitting unit in ascending order of bits.

For example, referring to FIG. 10, the 32 input ports of the 1^{st} multiplexer in the 1^{st} set of multiplexers are connected in a one-to-one correspondence to 32 output ports of the data splitting unit 2 starting from left; the 31 input ports of the 2^{nd} multiplexer in the 1^{st} set of multiplexers are connected in a one-to-one correspondence to the 2nd output port to the 32^{nd} output port corresponding to the data splitting unit 2 starting from left; and so on. Optionally, the 32^{nd} output port (that is, dout 32) corresponding to the data splitting unit 2 starting from left is not connected to the multiplexer. The output port may be directly outputted as the first element corresponding to a source sub-vector 1 starting from right.

In summary, in the technical resolutions provided in this example of the present subject matter, divide-and-conquer decompression of the target vector data is realized. Therefore, a plurality of multiplexers with a high parallelism degree are not required, a quantity of access ports of the multiplexers can be reduced, and a quantity of multiplexers to which the output ports of the target vector register need to be connected is reduced, thereby reducing a quantity of wires required for vector data decompression in the processor and wire intersections are reduced, significantly reducing a congestion level of the wires required for vector data decompression in the processor, and significantly reducing an area of the processor, especially an area of a processor with a high vector processing parallelism degree. The reduction of the area of the processor reduces manufacturing difficulty and manufacturing costs of the processor.

In addition, through the divide-and-conquer decompression of the target vector data, a decompression delay of the target vector data is reduced, thereby improving decompression efficiency of the target vector data.

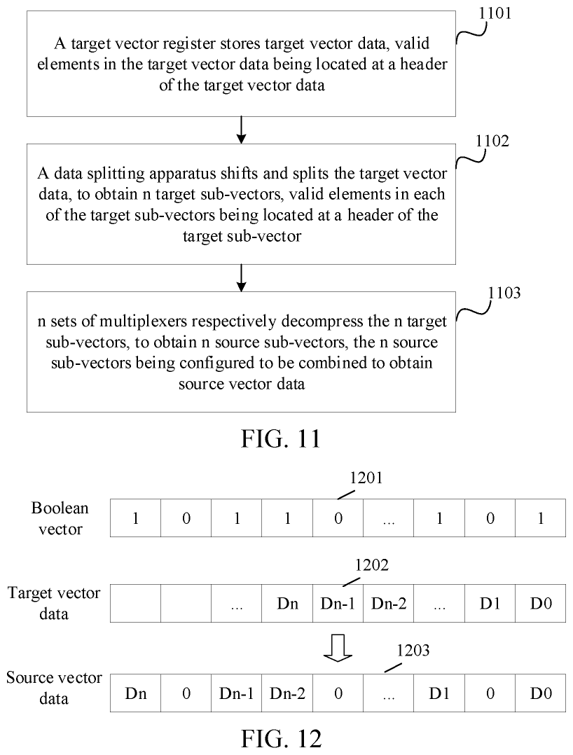

FIG. 11 is a flowchart of a method for decompressing vector data according to an example of the present subject matter. The method for decompressing vector data is performed by a processor, such as the processor shown in FIG. 9. The method may include the following steps (1101-1103).

Step 1101: A target vector register stores target vector data, valid elements in the target vector data are located at a header of the target vector data.

The target vector register may be configured to store only the valid elements in the target vector data, or may be configured to store all elements in the target vector data. Optionally, in a case that the target vector register stores only the valid elements in the target vector data, elements are filled based on a boolean vector, to obtain the target vector data. For example, referring to FIG. 12, valid elements (Dn-D0) in target vector data 1202 are located at a header of the target vector data 1202.

Step 1102: A data splitting apparatus shifts and splits the target vector data to obtain n target sub-vectors, valid elements in each of the target sub-vectors are located at a header of the target sub-vector.

The data splitting apparatus is configured to split the target vector data. The data splitting apparatus may extract the target vector data from the target vector register based on a data decompression instruction. Optionally, a value of n is not limited in this example of the present subject matter. For example, n may be set to a multiple of 2, or n may be set to a multiple of 4.

Optionally, the data splitting apparatus includes m sets of data splitting units, the m sets of data splitting units are configured to perform p rounds of shifting and splitting on the target vector data to obtain the n target sub-vectors, m is an integer greater than 1, and p is a positive integer.

Exemplarily, a q^{th} set of data splitting units in the m sets of data splitting units shifts and splits, for a q^{th} round of shifting and splitting, a q^{th} set of to-be-split vectors, to obtain a q^{th} set of split vectors, q is a positive integer less than or equal to p; and in a case that q is equal to 1, the q^{th} set of to-be-split vectors are the target vector data, and in a case that q is greater than 1, the q^{th} set of to-be-split vectors are a (q−1)^{th} set of split vectors, and a p^{th} set of split vectors are the n target sub-vectors.

For example, referring to FIG. 10, the data splitting apparatus includes 2 sets of data splitting units. The first set of data splitting units include the data splitting unit 1. The second set of data splitting units include the data splitting unit 2 and the data splitting unit 3. The first set of data splitting units are configured to shift and split the 1^{st} set of to-be-split vectors (that is, the target vector data) to obtain the 1^{st} set of split vectors. The second set of data splitting units are configured to shift and split the 2^{nd} set of to-be-split vectors (that is, the 1^{st} set of split vectors) to obtain the 2^{nd} set of split vectors, that is, 4 target sub-vectors (a target sub-vector 1 is composed of the outputs of the 32 output ports of the data splitting unit 2 starting from left, a target sub-vector 2 is composed of outputs of 32 output ports of the data splitting unit 2 starting from right, a target sub-vector 3 is composed of outputs of 32 output ports of the data splitting unit 3 starting from left, and a target sub-vector 4 is composed of outputs of 32 output ports of the data splitting unit 3 from the right, which are not shown in FIG. 10).

In an example, the q^{th} set of split vectors include s split vectors corresponding to the first to-be-split vector in the q^{th} set of to-be-split vectors. In a case that the first data splitting unit in the q^{th} set of data splitting units shifts and splits the first to-be-split vector in the q^{th} set of to-be-split vectors, the s split vectors corresponding to the first to-be-split vector may be obtained by using the following process.

The first data splitting unit determines s split element quantities corresponding to the first to-be-split vector, s is an integer greater than 1.

The first to-be-split vector may be any to-be-split vector in the q^{th} set of to-be-split vectors. The first data splitting unit may be a data splitting unit in the q^{th} set of data splitting units configured to shift and split the first to-be-split vector. A split element quantity is used for indicating an element quantity in an obtained split vector. s may be set and adjusted based on an actual use requirement.

For example, referring to FIG. 10, each to-be-split vector corresponds to 2 split element quantities. In other words, each data splitting unit splits a to-be-split vector into 2 split vectors. Optionally, quantities of elements in two split vectors corresponding to the same to-be-split vector are the same or different. In FIG. 10, the data splitting unit 1 splits the target vector data into two split vectors each having 64 elements, the data splitting unit 2 splits one of the split vectors having 64 elements into two split vectors each having 32 elements, that is, the target sub-vector 1 and the target sub-vector 2, and the data splitting unit 3 splits another vector to-be-split having 64 elements into two split vectors each having 32 elements, that is, the target sub-vector 3 and the target sub-vector 4.

2. The first data splitting unit determines s sets of valid split elements based on a boolean vector corresponding to the target vector data and the s split element quantities. An element in the boolean vector is used for indicating a distribution of valid elements in the source vector data.

For example, referring to FIG. 12, if it is assumed that the 1^{st} split element quantity is 5 in descending order of bits, a valid split element quantity corresponding to the 1^{st} split element quantity is 3 (that is, three 1 exist in 5 boolean values starting from left). In this way, the s sets of valid split elements respectively corresponding to the s split element quantities can be obtained.

3. The first data splitting unit respectively shifts the s sets of valid split elements as a whole in the first to-be-split vector based on the s sets of valid split elements, to obtain a shifted first to-be-split vector.

Optionally, the first data splitting unit determines, for a target split element quantity in the s split element quantities, a quantity of target to-be-shifted bits corresponding to the target split element quantity based on a difference between a position of a target valid split element corresponding to the target split element quantity in the first to-be-split vector and a position of the target split element corresponding to the target split element quantity in the boolean vector. The target valid split element corresponding to the target split element quantity is the last valid split element corresponding to the target split element quantity in descending order of bits, and the target split element corresponding to the target split element quantity is the last split element corresponding to the target split element quantity in descending order of bits. The target split element quantity is any split element quantity in the s split element quantities.

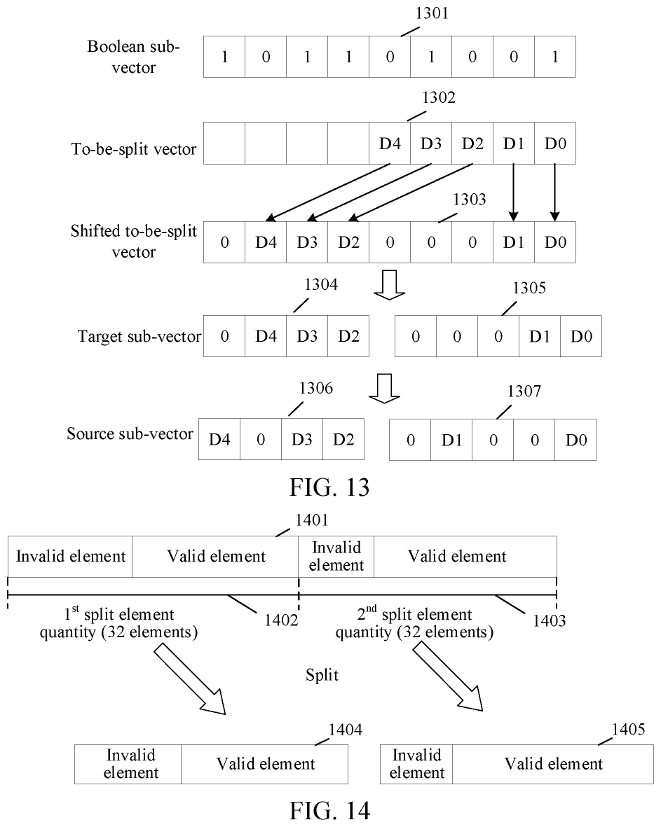

For example, referring to FIG. 13, in descending order of bits, the 1^{st} split element quantity is 4, and the 2^{nd} split element quantity is 5. The last valid split element corresponding to the 1^{st} split element quantity is located at the 7^{th} position of a to-be-split vector 1302. The last split element corresponding to the 1^{st} split element quantity is located at the 4^{th} position of a boolean sub-vector 1301. Therefore, a quantity of target to-be-shifted bits corresponding to the 1^{st} split element quantity may be: 7−4=3.

Optionally, in a case that the to-be-split vector corresponds to only 2 split element quantities, the valid split element quantity corresponding to the 1^{st} split element quantity may be directly determined as the quantity of target to-be-shifted bits corresponding to the 1^{st} split element quantity. For example, referring to FIG. 13, the 1^{st} split element quantity is 4, and the 2^{nd} split element quantity is 5. Based on the boolean sub-vector 1301, it may be determined that the 1^{st} split element quantity corresponds to 3 valid split elements. In this case, the quantity of target to-be-shifted bits corresponding to the 1^{st} split element quantity is 3.

The first data splitting unit shifts valid split elements in the first to-be-split vector corresponding to the target split element quantity as a whole based on the quantity of target to-be-shifted bits corresponding to the target split element quantity, to obtain an intermediate first to-be-split vector. The first data splitting unit further shifts the intermediate first to-be-split vector based on quantities of target to-be-shifted bits respectively corresponding to remaining split element quantities, to obtain the shifted first to-be-split vector. The remaining split element quantities are split element quantities in the s split element quantities other than the target split element quantity.

Exemplarily, the position of the target valid split element corresponding to the target split element quantity in the first to-be-split vector and the position of the target split element corresponding to the target split element quantity in the boolean vector are both positions in descending order of bits. The integral shifting of the valid split elements in the first to-be-split vector corresponding to the target split element quantity based on the quantity of target to-be-shifted bits corresponding to the target split element quantity means that the valid split elements in the first to-be-split vector corresponding to the target split element quantity are shifted toward a high bit as a whole by the quantity of target to-be-shifted bits.

For example, referring to FIG. 13, based on the foregoing examples, 3 valid split elements (D4, D3, and D2) corresponding to the 1^{st} split element quantity may be directly shifted toward a high bit by 3 bits in the to-be-split vector 1302, to obtain a shifted to-be-split vector 1303.

4. The first data splitting unit splits the shifted first to-be-split vector based on the s split element quantities, to obtain s split vectors corresponding to the first to-be-split vector.

Optionally, the s split vectors include a target split vector corresponding to the target split element quantity in the s split element quantities. The first data splitting unit determines a region corresponding to the target split vector corresponding to the target split element quantity in the boolean vector based on the target split element quantity. The first data splitting unit determines a target region corresponding to the target split vector in the shifted first to-be-split vector based on the region corresponding to the target split vector in the boolean vector. The first data splitting unit determines an element in the target region as an element of the target split vector. The target split vector is a split vector obtained through splitting of the shifted first to-be-split vector based on the target split element quantity.

For example, referring to FIG. 14, for a shifted first to-be-split vector 1401, the first data splitting unit determines a region corresponding to the 1^{st} split element quantity in the boolean vector based on the 1^{st} split element quantity, and then determines a target region 1402 corresponding to the 1^{st} split element quantity in a shifted first to-be-split vector 1401 based on the region corresponding to the 1^{st} split element quantity in the boolean vector, and may directly determine an element in the target region 1402 as an element corresponding to the 1^{st} split vector 1404. Similarly, an element in a target region 1403 corresponding to the 2^{nd} split element quantity in the shifted first to-be-split vector 1401 may be determined as an element corresponding to the 2^{nd} split vector 1405.

Optionally, the shifting method in this example of the present subject matter is the same as that described in the foregoing example. For content not described in this example of the present subject matter, refer to the foregoing examples, and the details are not described herein.

Step 1103: The n sets of multiplexers respectively decompress the n target sub-vectors, to obtain n source sub-vectors, the n source sub-vectors are configured to be combined to obtain source vector data.

Optionally, for a t^{th} target sub-vector in n target sub-vectors, a t^{th} set of multiplexers corresponding to the t^{th} target sub-vector determine a valid element position distribution corresponding to the t^{th} target sub-vector based on the boolean vector corresponding to the target vector data, t is a positive integer less than or equal to n. The t^{th} set of multiplexers successively arrange valid elements in the t^{th} target sub-vector to a position corresponding to the valid element position distribution in descending order of bits, to obtain a t^{th} source sub-vector corresponding to the t^{th} target sub-vector.

For example, referring to FIG. 13, a target sub-vector 1304 and a target sub-vector 1305 may be obtained through splitting of the shifted to-be-split vector 1303. A valid element position distribution in a source sub-vector 1306 corresponding to the target sub-vector 1304 may be determined based on the boolean sub-vector 1301. In addition, the source sub-vector 1306 may be obtained through successive adjustment of the valid elements in descending order of bits based on the valid element position distribution. Similarly, a source sub-vector 1307 corresponding to the target sub-vector 1305 may be obtained.

Optionally, the n source sub-vectors may be obtained through decompression of the n target sub-vectors by the n sets of multiplexers in sequence.

Optionally, the n source sub-vectors may be obtained through decompression of the n target sub-vectors by the n sets of multiplexers in parallel. In this way, efficiency of obtaining the n source sub-vectors can be further improved, thereby improving decompression efficiency of the vector data.

Optionally, after the n source sub-vectors are obtained, the n source sub-vectors may be combined to obtain source vector data. For example, referring to FIG. 12, n source sub-vectors corresponding to target vector data 1202 may be combined based on a boolean vector 1201 to obtain source vector data 1203.

Optionally, the hardware resources used during the implementation of the data compression instruction are similar to the hardware resources used during the implementation of the data decompression instruction. In an actual implementation, these resources (such as the multiplexers and the shifter) may be reused to further reduce the area of the processor.

In summary, in the technical resolutions provided in this example of the present subject matter, divide-and-conquer decompression of the target vector data is realized. Therefore, a plurality of multiplexers with a high parallelism degree are not required, a quantity of access ports of the multiplexers can be reduced, and a quantity of multiplexers to which the output ports of the target vector register need to be connected is reduced, thereby reducing a quantity of wires required for vector data decompression in the processor and wire intersections are reduced, significantly reducing a congestion level of the wires required for vector data decompression in the processor, and significantly reducing an area of the processor, especially an area of a processor with a high vector processing parallelism degree. The reduction of the area of the processor reduces manufacturing difficulty and manufacturing costs of the processor.

In addition, through the divide-and-conquer decompression of the target vector data, a decompression delay of the target vector data is reduced, thereby improving decompression efficiency of the target vector data.

An apparatus example of the present subject matter is described below, which may be used for performing the method example of the present subject matter. For details not disclosed in the apparatus example of the present subject matter, refer to the foregoing examples of the present subject matter.

FIG. 15 is a block diagram of an apparatus for compressing vector data according to an example of the present subject matter. The apparatus has a function of implementing the foregoing method. The function may be implemented by hardware or by executing corresponding software by hardware. The apparatus may be the computer device described above, or may be arranged in the computer device. As shown in FIG. 15, the apparatus 1500 includes: a source data storage module 1501, a sub-vector compression module 1502, a sub-vector merging module 1503, and a target data storage module 1504.

The source data storage module 1501 is configured to control a source vector register to store source vector data, the source vector data is divided into n source sub-vectors, the n source sub-vectors are in a one-to-one correspondence with n sets of multiplexers.

The sub-vector compression module 1502 is configured to control an i^{th} set of multiplexers in the n sets of multiplexers to selectively arrange valid elements in an i^{th} source sub-vector in the source vector data, to obtain an i^{th} target sub-vector corresponding to the i^{th} source sub-vector, valid elements in the i^{th} target sub-vector is located at a header of the i^{th} target sub-vector, and i is a positive integer less than or equal to n.

The sub-vector merging module 1503 is configured to control a data merging apparatus to shift and merge n target sub-vectors corresponding to the n source sub-vectors, to obtain target vector data, valid elements in the target vector data are located at a header of the target vector data.

The target data storage module 1504 is configured to control a target vector register to store the valid elements in the target vector data.

In an example, the i^{th} source sub-vector includes x elements, the x elements including y valid elements, and the i^{th} set of multiplexers including x−1 multiplexers of different types, x is a positive integer, and y is a positive integer less than or equal to x−1.

The sub-vector compression module 1502 is configured to control y multiplexers in the x−1 multiplexers to select the y valid elements from the x elements in ascending order of bits based on a boolean vector corresponding to the source vector data, and arrange the y valid elements in ascending order of bits, to obtain the i^{th} target sub-vector, an element in the boolean vector is used for indicating a distribution of the valid elements in the source vector data.

In an example, the sub-vector compression module 1502 is configured to: control a z^{th} multiplexer in the y multiplexers to select a z^{th} valid element from a z^{th} element to an x^{th} element in the i^{th} source sub-vector in ascending order of bits based on the boolean vector, z is a positive integer less than or equal to y; and control the z^{th} multiplexer to add the z^{th} valid element to a z^{th} position of the i^{th} target sub-vector.

In an example, the data merging apparatus includes m sets of data merging units, the m sets of data merging units are configured to perform p rounds of shifting and merging on the n target sub-vectors to obtain the target vector data, m is an integer greater than 1, and p is a positive integer. The sub-vector merging module 1503 is configured to control, for a q^{th} round of shifting and merging, a q^{th} set of data merging units in the m sets of data merging units to shift and merge a CO set of to-be-merged vectors, to obtain a q^{th} set of merged vectors, q is a positive integer less than or equal to p; and in a case that q is equal to 1, the q^{th} set of to-be-merged vectors are the n target sub-vectors, and in a case that q is greater than 1, the q^{th} set of to-be-merged vectors are a (q−1)^{th} set of merged vectors, and a p^{th} set of merged vectors are the target vector data.

In an example, the sub-vector merging module 1503 is configured to control the data merging units in the q^{th} sets of data merging units to shift and merge each two adjacent to-be-merged vectors in the q^{th} set of to-be-merged vectors, to obtain the q^{th} set of merged vectors.

In an example, the sub-vector merging module 1503 is further configured to control the data merging apparatus to add a target to-be-merged vector in the q^{th} set of to-be-merged vectors to the q^{th} set of merged vectors in a case that a quantity of data merging units in the q^{th} set of data merging units is an odd number, the target to-be-merged vector in the q^{th} set of to-be-merged vectors are the first to-be-merged vector or the last to-be-merged vector in the q^{th} set of to-be-merged vectors in ascending order of bits.

In an example, in a case that the first data merging unit in the q^{th} set of data merging units shifts and merges the first to-be-merged vector and the second to-be-merged vector in the q^{th} set of to-be-merged vectors, the sub-vector merging module 1503 is configured to: control the first data merging unit to shift the first to-be-merged vector based on the second to-be-merged vector, to obtain an adjusted first to-be-merged vector; and control the first data merging unit to merge the adjusted first to-be-merged vector and the second to-be-merged vector, to obtain a first merged vector corresponding to the q^{th} set of merged vectors, an element corresponding to the second to-be-merged vector in the source vector data is at a lower bit than an element corresponding to the first to-be-merged vector in the source vector data.

In an example, the sub-vector merging module 1503 is configured to: control the first data merging unit to fill the first to-be-merged vector with elements based on a quantity of elements in the second to-be-merged vector, to obtain a filled first to-be-merged vector, a quantity of elements in the filled first to-be-merged vector is a sum of the quantity of the elements in the second to-be-merged vector and a quantity of elements in the first to-be-merged vector; and control the first data merging unit to shift non-filling elements in the filled first to-be-merged vector as a whole based on a quantity of invalid elements in the second to-be-merged vector, to obtain the adjusted first to-be-merged vector, a quantity of non-filling elements corresponding to a header of the adjusted first to-be-merged vector is the same as the quantity of the valid elements in the second to-be-merged vector.

In an example, the sub-vector merging module 1503 is configured to: control the first data merging unit to select elements corresponding to the first merged vector from the adjusted first to-be-merged vector and the second to-be-merged vector in ascending order of bits; and control, for a k^{th} element corresponding to the first merged vector, the first data merging unit to select one of a k^{th} element in the adjusted first to-be-merged vector and a k^{th} element in the second to-be-merged vector as the k^{th} element corresponding to the first merged vector, k is a positive integer.

In an example, the sub-vector merging module 1503 is configured to: control the first data merging unit to determine the k^{th} element in the adjusted first to-be-merged vector as the k^{th} element corresponding to the first merged vector in a case that the k^{th} element in the adjusted first to-be-merged vector is a valid element; or control the first data merging unit to determine the k^{th} element in the second to-be-merged vector as the k^{th} element corresponding to the first merged vector in a case that the k^{th} element in the second to-be-merged vector is a valid element.

In an example, the n target sub-vectors are obtained through selective arrangement of valid elements of the n source sub-vectors performed by the n sets of multiplexers in parallel.

In summary, in the technical resolutions provided in the examples of the present subject matter, the n source sub-vectors divided from the source vector data are compressed respectively by using the n sets of multiplexers, to obtain the n target sub-vectors. Then, the n target sub-vectors are shifted and merged to obtain target vector data, that is, compressed source vector data. In this way, divide-and-conquer processing of vector data is implemented. Therefore, a plurality of multiplexers with a high parallelism degree are not required, a quantity of access ports of the multiplexers can be reduced, and a quantity of multiplexers to which the output ports of the source vector register need to be connected is reduced, thereby reducing a quantity of wires required for vector data compression in the processor and wire intersections are reduced, significantly reducing a congestion level of the wires required for vector data compression in the processor, and significantly reducing an area of the processor, especially an area of a processor with a high vector processing parallelism degree. The reduction of the area of the processor reduces manufacturing difficulty and manufacturing costs of the processor.

In addition, since the n source sub-vectors are compressed respectively by using the n sets of multiplexers, a compression delay of the vector data is reduced, and compression efficiency of the vector data is improved.

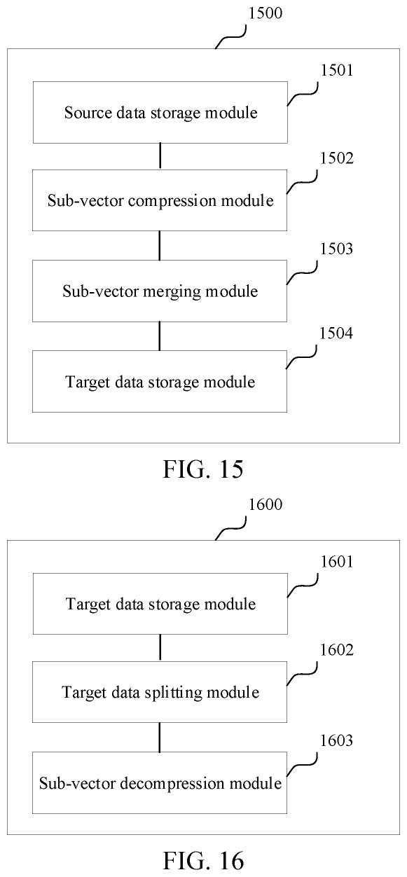

FIG. 16 is a block diagram of an apparatus for decompressing vector data according to an example of the present subject matter. The apparatus has a function of implementing the foregoing method. The function may be implemented by hardware or by executing corresponding software by hardware. The apparatus may be the computer device described above, or may be arranged in the computer device. As shown in FIG. 16, the apparatus 1600 includes a target data storage module 1601, a target data splitting module 1602, and a sub-vector decompression module 1603.

The target data storage module 1601 is configured to control a target vector register to store target vector data, valid elements in the target vector data is located at a header of the target vector data.

The target data splitting module 1602 is configured to control a data splitting apparatus to shift and split the target vector data, to obtain n target sub-vectors, valid elements in each of the target sub-vectors are located at a header of the target sub-vector.

The sub-vector decompression module 1603 is configured to control n sets of multiplexers to respectively decompress the n target sub-vectors, to obtain n source sub-vectors, the n source sub-vectors are configured to be combined to obtain source vector data.

In an example, the data splitting apparatus includes m sets of data splitting units, the m sets of data splitting units are configured to perform p rounds of shifting and splitting on the target vector data to obtain the n target sub-vectors, m is an integer greater than 1, and p is a positive integer.

The target data splitting module 1602 is configured to control, for a q^{th} round of shifting and splitting, a q^{th} set of data splitting units in the m sets of data splitting units to shift and split a q^{th} set of to-be-split vectors, to obtain a q^{th} set of split vectors, q is a positive integer less than or equal to p; and in a case that q is equal to 1, the q^{th} set of to-be-split vectors are the target vector data, and in a case that q is greater than 1, the q^{th} set of to-be-split vectors are a (q−1)^{th} set of split vectors, and a p^{th} set of split vectors are the n target sub-vectors.

In an example, the q^{th} set of split vectors include s split vectors corresponding to a first to-be-split vector in the q^{th} set of to-be-split vectors, s is an integer greater than 1. In a case that a first data splitting unit in the q^{th} set of data splitting units shifts and splits the first to-be-split vector, the target data splitting module 1602 is configured to: control the first data splitting unit to determine s split element quantities corresponding to the first to-be-split vector; control the first data splitting unit to determine s sets of valid split elements based on a boolean vector corresponding to the target vector data and the s split element quantities, an element in the boolean vector is used for indicating a distribution of the valid elements in the source vector data; control the first data splitting unit in the first to-be-split vector to respectively shift the s sets of valid split elements as a whole in the first to-be-split vector based on the s sets of valid split elements, to obtain a shifted first to-be-split vector; and control the first data splitting unit to split the shifted first to-be-split vector based on the s split element quantities, to obtain s split vectors corresponding to the first to-be-split vector.

In an example, the target data splitting module 1602 is configured to: control, for a target split element quantity in the s split element quantities, the first data splitting unit to determine a quantity of target to-be-shifted bits based on a difference between a position of a target valid split element corresponding to the target split element quantity in the first to-be-split vector and a position of a target split element corresponding to the target split element quantity in the boolean vector, the target valid split element corresponding to the target split element quantity is the last valid split element corresponding to the target split element quantity in descending order of bits, and the target split element corresponding to the target split element quantity is the last split element corresponding to the target split element quantity in descending order of bits; control the first data splitting unit to shift valid split elements in the first to-be-split vector corresponding to the target split element quantity as a whole based on the quantity of target to-be-shifted bits, to obtain an intermediate first to-be-split vector; and control the first data splitting unit to further shift the intermediate first to-be-split vector based on quantities of target to-be-shifted bits respectively corresponding to remaining split element quantities, to obtain the shifted first to-be-split vector.

In an example, the s split vectors include a target split vector corresponding to a target split element quantity in the s split element quantities. The target data splitting module 1602 is configured to: control the first data splitting unit to determine a region corresponding to the target split vector corresponding to the target split element quantity in the boolean vector based on the target split element quantity; control the first data splitting unit to determine a target region corresponding to the target split vector in the shifted first to-be-split vector based on the region corresponding to the target split vector in the boolean vector; and control the first data splitting unit to determine an element in the target region as an element of the target split vector.

In an example, the sub-vector decompression module 1603 is configured to: control, for a t^{th} target sub-vector in the n target sub-vectors, a t^{th} set of multiplexers in the n sets of multiplexers corresponding to the t^{th} target sub-vector to determine a valid element position distribution corresponding to the t^{th} target sub-vector based on the boolean vector corresponding to the target vector data, t is a positive integer less than or equal to n; and control the t^{th} set of multiplexers to successively arrange valid elements in the t^{th} target sub-vector to a position corresponding to the valid element position distribution in descending order of bits, to obtain a t^{th} source sub-vector corresponding to the t^{th} target sub-vector.

In an example, the n source sub-vectors are obtained through decompression of the n target sub-vectors by the n sets of multiplexers in parallel.

In summary, in the technical resolutions provided in this example of the present subject matter, divide-and-conquer decompression of the target vector data is realized. Therefore, a plurality of multiplexers with a high parallelism degree are not required, a quantity of access ports of the multiplexers can be reduced, and a quantity of multiplexers to which the output ports of the target vector register need to be connected is reduced, thereby reducing a quantity of wires. The resolutions provided in the present subject matter may further reduce the quantity wires required in the processor and the quantity of wire intersections, significantly reducing a congestion level of the wires required for vector data decompression in the processor, and significantly reducing an area of the processor, especially an area of a processor with a high vector processing parallelism degree. The reduction of the area of the processor reduces manufacturing difficulty and manufacturing costs of the processor.

In addition, through the divide-and-conquer decompression of the target vector data, a decompression delay of the target vector data is reduced, thereby improving decompression efficiency of the target vector data.

It is to be understood that, during function implementation of the apparatus provided in the foregoing example, only division of the functional modules is illustrated. In actual application, the functions may be assigned to different functional modules for completion as required. In other words, an internal structure of the device is divided into different functional modules to complete all or some of the functions described above. In addition, the apparatus in the foregoing example belongs to the same idea as the method. For a specific implementation thereof, refer to the method example, and the details are not described herein.

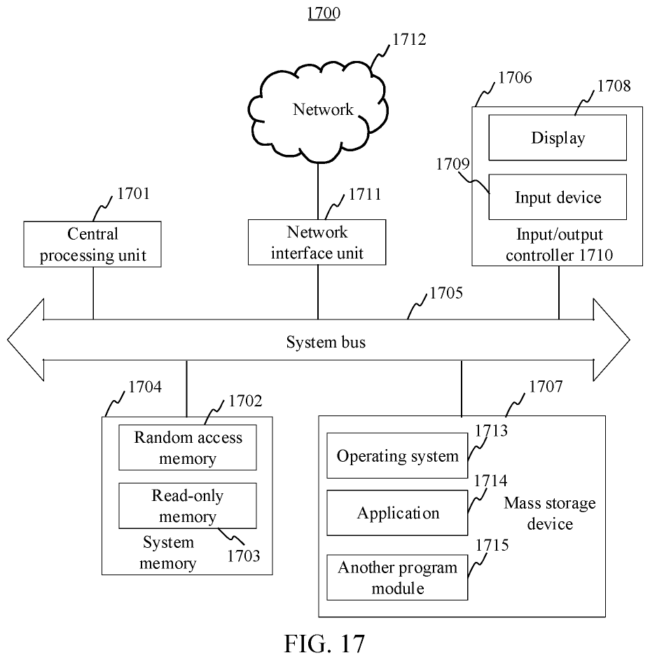

FIG. 17 is a structural block diagram of a computer device according to an example of the present subject matter. The computer device may be configured to implement the method for compressing vector data or the method for decompressing vector data provided in the foregoing examples. Details may be as follows:

The computer device 1700 includes a central processing unit (CPU), a graphics processing unit (GPU), a field programmable gate array (FPGA) 1701, a system memory 1704 including a random access memory (RAM) 1702 and a read-only memory (ROM) 1703, and a system bus 1705 connecting the system memory 1704 and the CPU 1701. The computer device 1700 further includes a basic input/output system (I/O system) 1706 assisting information transmission between devices in a server, and a mass storage device 1707 configured to store an operating system 1713, an application 1714, and another program module 1715.

The basic input/output system 1706 includes a display 1708 configured to display information and an input device 1709, such as a mouse or a keyboard for a user to input information. The display 1708 and the input device 1709 are both connected to the CPU 1701 through an input/output controller 1710 connected to the system bus 1705. The basic input/output system 1706 may further include the input/output system controller 1710 for receiving and processing an input from a plurality of other devices such as a keyboard, a mouse, or an electronic stylus. Similarly, the input/output controller 1710 further provides an output to a display screen, a printer, or another type of output device.

The mass storage device 1707 is connected to the CPU 1701 through a mass storage controller (not shown) connected to the system bus 1705. The mass storage device 1707 and an associated non-transitory computer-readable medium thereof provide non-volatile storage for the computer device 1700. In other words, the mass storage device 1707 may include a non-transitory computer-readable medium (not shown) such as a hard disk or a compact disc read-only memory (CD-ROM) drive.

Without loss of generality, the non-transitory computer-readable medium may include a computer storage medium and a communication medium. The computer storage medium includes volatile and non-volatile media, and removable and non-removable media implemented by using any method or technology used for storing information such as computer-readable instructions, data structures, program modules, or other data. The computer storage medium includes a RAM, a ROM, an erasable programmable read-only memory (EPROM), an electrically erasable programmable ROM (EEPROM), a flash memory or another solid-state storage technology, a CD-ROM, a digital versatile disc (DVD) or another optical memory, a tape cartridge, a magnetic cassette, a magnetic disk memory, or another magnetic storage device. Certainly, a person skilled in the art may learn that the computer storage medium is not limited to the above. The foregoing system memory 1704 and mass storage device 1707 may be collectively referred to as a memory.

The term module (and other similar terms such as unit, subunit, submodule, etc.) in the present disclosure may refer to a software module, a hardware module, or a combination thereof. Modules implemented by software are stored in memory or non-transitory computer-readable medium. The software modules, which include computer instructions or computer code, stored in the memory or medium can run on a processor or circuitry (e.g., ASIC, PLA, DSP, FPGA, or other integrated circuit) capable of executing computer instructions or computer code. A hardware module may be implemented using one or more processors or circuitry. A processor or circuitry can be used to implement one or more hardware modules. Each module can be part of an overall module that includes the functionalities of the module. Modules can be combined, integrated, separated, and/or duplicated to support various applications. Also, a function being performed at a particular module can be performed at one or more other modules and/or by one or more other devices instead of or in addition to the function performed at the particular module. Further, modules can be implemented across multiple devices and/or other components local or remote to one another. Additionally, modules can be moved from one device and added to another device, and/or can be included in both devices and stored in memory or non-transitory computer readable medium.

According to the examples of the present subject matter, the computer device 1700 may be further connected to a remote computer on a network for running through a network such as the Internet. In other words, the computer device 1700 may be connected to a network 1712 through a network interface unit 1711 connected to the system bus 1705, or may be connected to another type of network or remote computer system (not shown) through the network interface unit 1711.

The memory further includes at least one instruction, at least one program, a code set or an instruction set. The at least one instruction, the at least one program, the code set, or the instruction set is stored in the memory and is configured to be executed by a processor to cause a computer device to implement the foregoing method for compressing vector data or the foregoing method for decompressing vector data.

In an example, a non-volatile, non-transitory computer-readable storage medium is further provided. The non-volatile, non-transitory computer-readable storage medium stores at least one instruction, at least one program, a code set, or an instruction set. The at least one instruction, the at least one program, the code set, or the instruction set, when executed by a processor, causes a computer to implement the foregoing method for compressing vector data or the foregoing method for decompressing vector data.

Optionally, the non-volatile, non-transitory computer-readable storage medium may include a ROM, a RAM, a solid state drive (SSD), an optical disc, or the like. The RAM may include a resistance random access memory (ReRAM) and a dynamic random access memory (DRAM).

In an example, a computer program product or a computer program is further provided. The computer program product or the computer program includes computer instructions. The computer instructions are stored in a non-volatile, non-transitory computer-readable storage medium. A processor of a computer device reads the computer instructions from the non-volatile, non-transitory computer-readable storage medium, and executes the computer instructions to cause the computer device to perform the foregoing method for compressing vector data or the foregoing method for decompressing vector data.

The information (including but not limited to device information of an object and personal information of an object), data (including but not limited to data used for analysis, stored data, and displayed data), and signals in the present subject matter are all authorized by the object or fully authorized by all parties, and collection, use, and processing of relevant data need to comply with relevant laws, regulations, and standards of relevant countries and regions. For example, the wiring manner, the hardware architecture of the processor, and the like in the present subject matter are obtained after full authorization.

It is to be understood that the term “a plurality of” mentioned herein means two or more. “And/or” describes an association relationship between associated objects and indicates that three relationships may exist. For example, A and/or B may represent the following three cases: Only A exists, both A and B exist, and only B exists. The character “/” generally indicates an “or” relationship between the associated objects. In addition, the step numbers described herein merely show a possible execution sequence of the steps. In some other examples, the steps may not be performed according to the number sequence. For example, two steps with different numbers may be performed simultaneously, or two steps with different numbers may be performed according to a sequence reverse to the sequence shown in the figure. This is not limited in the examples of the present subject matter.

The foregoing descriptions are merely examples of the present subject matter, and are not intended to limit the present subject matter. Any modification, equivalent replacement, or improvement made within the spirit and principle of the present subject matter falls within the protection scope of the present subject matter.

What is claimed is:

1. A method for compressing vector data by a processor comprising a source vector register, n sets of multiplexers, a data merging apparatus, and a target vector register, where n is an integer greater than 1, the method comprising:
storing, by the source vector register, source vector data, wherein
the source vector data is divided into n source sub-vectors, and
the n source sub-vectors are in a one-to-one correspondence with the n sets of multiplexers;
selectively arranging, by an i^{th} set of multiplexers in the n sets of multiplexers, first valid elements in an i^{th} source sub-vector in the source vector data to obtain an i^{th} target sub-vector corresponding to the i^{th} source sub-vector, wherein
the first valid elements in the i^{th} target sub-vector are located at a header of the i^{th} target sub-vector, and
i is a positive integer less than or equal to n;
shifting and merging, by the data merging apparatus, n target sub-vectors corresponding to the n source sub-vectors to obtain target vector data, wherein
second valid elements in the target vector data are located at a header of the target vector data; and
storing, by the target vector register, the second valid elements in the target vector data.

2. The method according to claim 1, wherein
the i^{th} source sub-vector comprises x elements,
the x elements comprising y valid elements, and
the i^{th} set of multiplexers comprising x−1 multiplexers of different types, x is a positive integer, and y is a positive integer less than or equal to x−1; and
the selectively arranging comprises:
selecting, by y multiplexers in the x−1 multiplexers, the y valid elements from the x elements in ascending order of bits based on a boolean vector corresponding to the source vector data, and arranging the y valid elements in ascending order of bits to obtain the i^{th} target sub-vector, wherein
an element in the boolean vector is used for indicating a distribution of the valid elements in the source vector data.

3. The method according to claim 2, wherein the selecting comprises:
selecting, by a z^{th} multiplexer in the y multiplexers, a z^{th} valid element from a z^{th} element to an x^{th} element in the i^{th} source sub-vector in ascending order of bits based on the boolean vector, wherein
z is a positive integer less than or equal to y; and
adding, by the z^{th} multiplexer, the z^{th} valid element to a z^{th} position of the i^{th} target sub-vector.

4. The method according to claim 1, wherein
the data merging apparatus comprises:
m sets of data merging units, wherein
the m sets of data merging units are configured to perform p rounds of shifting and merging on the n target sub-vectors to obtain the target vector data, and
m is an integer greater than 1, and p is a positive integer; and
the shifting and merging comprises:
shifting and merging, by a q^{th} set of data merging units in the m sets of data merging units for a q^{th} round of shifting and merging, a q^{th} set of to-be-merged vectors to obtain a q^{th} set of merged vectors, wherein
q is a positive integer less than or equal to p; and
in a case that q is equal to 1, the q^{th} set of to-be-merged vectors are the n target sub-vectors, and in a case that q is greater than 1, wherein
the q^{th} set of to-be-merged vectors are a (q−1)^{th} set of merged vectors, and
a p^{th} set of merged vectors are the target vector data.

5. The method according to claim 4, wherein the shifting and merging further comprises:
shifting and merging, by the data merging units in the q^{th} set of data merging units, each two adjacent to-be-merged vectors in the q^{th} set of to-be-merged vectors to obtain the q^{th} set of merged vectors.

6. The method according to claim 5, further comprising:
adding, by the data merging apparatus, a target to-be-merged vector in the q^{th} set of to-be-merged vectors to the q^{th} set of merged vectors in a case that a quantity of to-be-merged vectors in the q^{th} set of to-be-merged vectors is an odd number, wherein
the target to-be-merged vector in the q^{th} set of to-be-merged vectors is the first to-be-merged vector or the last to-be-merged vector in the q^{th} set of to-be-merged vectors in ascending order of bits.

7. The method according to claim 5, wherein
in a case that a first data merging unit in the q^{th} set of data merging units shifts and merges a first to-be-merged vector and a second to-be-merged vector in the q^{th} set of to-be-merged vectors, the shifting and merging comprises:
shifting, by the first data merging unit, the first to-be-merged vector based on the second to-be-merged vector to obtain an adjusted first to-be-merged vector; and
merging, by the first data merging unit, the adjusted first to-be-merged vector and the second to-be-merged vector to obtain a first merged vector corresponding to the q^{th} set of merged vectors, wherein
an element corresponding to the second to-be-merged vector in the source vector data is at a lower bit than an element corresponding to the first to-be-merged vector in the source vector data.

8. The method according to claim 7, wherein the shifting comprises:
filling, by the first data merging unit, the first to-be-merged vector with elements based on a quantity of elements in the second to-be-merged vector to obtain a filled first to-be-merged vector, wherein
a quantity of elements in the filled first to-be-merged vector is a sum of the quantity of the elements in the second to-be-merged vector and a quantity of elements in the first to-be-merged vector; and
shifting, by the first data merging unit, non-filling elements in the filled first to-be-merged vector as a whole based on a quantity of invalid elements in the second to-be-merged vector to obtain the adjusted first to-be-merged vector, wherein
a quantity of non-filling elements corresponding to a header of the adjusted first to-be-merged vector is the same as the quantity of the valid elements in the second to-be-merged vector.

9. The method according to claim 7, wherein the merging comprises:
selecting, by the first data merging unit, elements corresponding to the first merged vector from the adjusted first to-be-merged vector and the second to-be-merged vector in ascending order of bits; and
selecting, by the first data merging unit for a k^{th} element corresponding to the first merged vector, one of a k^{th} element in the adjusted first to-be-merged vector and a k^{th} element in the second to-be-merged vector as the k^{th} element corresponding to the first merged vector, wherein
k is a positive integer.

10. The method according to claim 9, wherein the selecting, by the first data merging unit, one of a k^{th} element in the adjusted first to-be-merged vector and a k^{th} element in the second to-be-merged vector as the k^{th} element corresponding to the first merged vector comprises:
determining, by the first data merging unit, the k^{th} element in the adjusted first to-be-merged vector as the k^{th} element corresponding to the first merged vector in a case that the k^{th} element in the adjusted first to-be-merged vector is a valid element; or
determining, by the first data merging unit, the k^{th} element in the second to-be-merged vector as the k^{th} element corresponding to the first merged vector in a case that the k^{th} element in the second to-be-merged vector is a valid element.

11. The method according to claim 1, wherein the n target sub-vectors are obtained through selective arrangement of valid elements of the n source sub-vectors performed by the n sets of multiplexers in parallel.

12. A method for decompressing vector data by a processor comprising a target vector register, a data splitting apparatus, and n sets of multiplexers, wherein n is an integer greater than 1, the method comprising:
storing, by the target vector register, target vector data, wherein
first valid elements in the target vector data are located at a header of the target vector data;
shifting and splitting, by the data splitting apparatus, the target vector data to obtain n target sub-vectors, wherein
second valid elements in each of the target sub-vectors are located at a header of the target sub-vector; and
respectively decompressing, by the n sets of multiplexers, the n target sub-vectors to obtain n source sub-vectors, wherein
the n source sub-vectors are configured to be combined to obtain source vector data.

13. The method according to claim 12, wherein the data splitting apparatus comprises m sets of data splitting units, the m sets of data splitting units are configured to perform p rounds of shifting and splitting on the target vector data to obtain the n target sub-vectors, wherein m is an integer greater than 1, and p is a positive integer; and the shifting and splitting comprises:
shifting and splitting, by a q^{th} set of data splitting units in the m sets of data splitting units for a q^{th} round of shifting and splitting a q^{th} set of to-be-split vectors to obtain a q^{th} set of split vectors, wherein
q is a positive integer less than or equal to p; and
in a case that q is equal to 1,
the q^{th} set of to-be-split vectors are the target vector data, and
in a case that q is greater than 1,
the q^{th} set of to-be-split vectors are a (q−1)^{th} set of split vectors, and
a p^{th} set of split vectors are the n target sub-vectors.

14. The method according to claim 13, wherein
the q^{th} set of split vectors comprise s split vectors corresponding to a first to-be-split vector in the q^{th} set of to-be-split vectors, wherein
s is an integer greater than 1; and
in a case that a first data splitting unit in the q^{th} set of data splitting units shifts and splits the first to-be-split vector, the s split vectors corresponding to the first to-be-split vector are obtained in the following manner:
determining, by the first data splitting unit, s split element quantities corresponding to the first to-be-split vector;
determining, by the first data splitting unit, s sets of valid split elements based on a boolean vector corresponding to the target vector data and the s split element quantities, an element in the boolean vector is used for indicating a distribution of valid elements in the source vector data;
respectively shifting, by the first data splitting unit, the s sets of valid split elements as a whole in the first to-be-split vector based on the s sets of valid split elements to obtain a shifted first to-be-split vector; and
splitting, by the first data splitting unit, the shifted first to-be-split vector based on the s split element quantities to obtain s split vectors corresponding to the first to-be-split vector.

15. The method according to claim 14, wherein the respectively shifting comprises:
determining, by the first data splitting unit for a target split element quantity in the s split element quantities, a quantity of target to-be-shifted bits corresponding to the target split element quantity based on a difference between a position of a target valid split element corresponding to the target split element quantity in the first to-be-split vector and a position of the target split element corresponding to the target split element quantity in the boolean vector;
shifting, by the first data splitting unit, valid split elements in the first to-be-split vector corresponding to the target split element quantity as a whole based on the quantity of target to-be-shifted bits corresponding to the target split element quantity to obtain an intermediate first to-be-split vector; and
further shifting, by the first data splitting unit, the intermediate first to-be-split vector based on quantities of target to-be-shifted bits respectively corresponding to remaining split element quantities to obtain the shifted first to-be-split vector, wherein
the target valid split element corresponding to the target split element quantity is the last valid split element corresponding to the target split element quantity in descending order of bits, and
the target split element corresponding to the target split element quantity is the last split element corresponding to the target split element quantity in descending order of bits.

16. The method according to claim 14, wherein
the s split vectors comprise a target split vector corresponding to a target split element quantity in the s split element quantities; and
the splitting comprises:
determining, by the first data splitting unit, a region corresponding to the target split vector corresponding to the target split element quantity in the boolean vector based on the target split element quantity;
determining, by the first data splitting unit, a target region corresponding to the target split vector in the shifted first to-be-split vector based on the region corresponding to the target split vector in the boolean vector; and
determining, by the first data splitting unit, an element in the target region as an element of the target split vector.

17. The method according to claim 12, wherein
the respectively decompressing comprises:
determining, by a t^{th} set of multiplexers in the n sets of multiplexers for a t^{th} target sub-vector in the n target sub-vectors, a valid element position distribution corresponding to the t^{th} target sub-vector in the n target sub-vectors based on a boolean vector corresponding to the target vector data, wherein
t is a positive integer less than or equal to n; and
successively arranging, by the t^{th} set of multiplexers, valid elements in the t^{th} target sub-vector to a position corresponding to the valid element position distribution in descending order of bits to obtain a t^{th} source sub-vector corresponding to the t^{th} target sub-vector.

18. The method according to claim 12, wherein
the n source sub-vectors are obtained through decompression of the n target sub-vectors by the n sets of multiplexers in parallel.

19. A method for compressing and decompressing vector data by a processor comprising a source vector register, a target vector register, n sets of multiplexers, a data merging apparatus, and a data splitting apparatus, where n is an integer greater than 1, the method comprising:
compressing the vector data, comprising:
storing, by the source vector register, source vector data, wherein
the source vector data is divided into n source sub-vectors, and
the n source sub-vectors are in a one-to-one correspondence with the n sets of multiplexers;
selectively arranging, by an i^{th} set of multiplexers in the n sets of multiplexers, first valid elements in an i^{th} source sub-vector in the source vector data to obtain an i^{th} target sub-vector corresponding to the i^{th} source sub-vector, wherein
the first valid elements in the i^{th} target sub-vector are located at a header of the i^{th} target sub-vector, and
i is a positive integer less than or equal to n;
shifting and merging, by the data merging apparatus, n target sub-vectors corresponding to the n source sub-vectors to obtain target vector data, wherein
second valid elements in the target vector data are located at a first header of the target vector data;
storing, by the target vector register, the second valid elements in the target vector data; and
decompressing the vector data, wherein
third valid elements in the target vector data are located at a second header of the target vector data;
shifting and splitting, by the data splitting apparatus, the target vector data to obtain n target sub-vectors, wherein
fourth valid elements in each of the target sub-vectors are located at a header of the target sub-vector; and
respectively decompressing, by the n sets of multiplexers, the n target sub-vectors to obtain the n source sub-vectors, wherein
the n source sub-vectors are configured to be combined to obtain source vector data.
